(19) United States
(12) Patent Application Publication
(10) Pub. No.: US 2025/0072001 A1
(43) Pub. Date: Feb. 27, 2025

(54) SEMICONDUCTOR DEVICE HAVING MEMORY STRINGS ARRANGED IN A VERTICAL DIRECTION

(71) Applicant: SAMSUNG ELECTRONICS CO., LTD., SUWON-SI (KR)

(72) Inventors: Hanbyeol LEE, Suwon-si (KR); Sukkang SUNG, Suwon-si (KR); Younghwan SON, Suwon-si (KR)

(21) Appl. No.: 18/800,667

(22) Filed: Aug. 12, 2024

(30) Foreign Application Priority Data
Aug. 24, 2023 (KR) 10-2023-0111534

(51) Int. Cl. H10B 43/40; G11C 16/04; H01L 23/528; H01L 23/532; H01L 25/065; H10B 43/10; H10B 43/27; H10B 43/35; H10B 80/00

(52) U.S. Cl. CPC H10B 43/40; G11C 16/0483; H01L 23/5283; H01L 23/53295; H01L 25/0657; H10B 43/10; H10B 43/27; H10B 43/35; H10B 80/00; H01L 2225/06506

(57) ABSTRACT

A semiconductor device includes: a peripheral circuit structure including a substrate and a circuit that is disposed on the substrate; a cell structure disposed on the peripheral circuit structure and including gate electrodes and a channel that extends through the gate electrodes; and a bonding structure located between the peripheral circuit structure and the cell structure, wherein the bonding structure includes: a first insulating layer attached to the peripheral circuit structure; a first bonding pad disposed on the peripheral circuit structure and electrically connected to the circuit; a second insulating layer attached to the cell structure; a second bonding pad disposed on the cell structure and electrically connected to the gate electrodes; and an anisotropic conductive adhesive layer located between the first insulating layer and the second insulating layer and between the first bonding pad and the second bonding pad, and including a plurality of conductive particles.

### CROSS-REFERENCE TO RELATED APPLICATION

This application claims priority under 35 USC § 119 to Korean Patent Application No. 10-2023-0111534, filed on Aug. 24, 2023, in the Korean Intellectual Property Office, the disclosure of which is incorporated by reference herein in its entirety.

### TECHNICAL FIELD

Embodiments of the present inventive concept relate to a semiconductor device, and more particularly, to a semiconductor device having memory strings arranged in a vertical direction.

### DISCUSSION OF THE RELATED ART

In electronic systems that use data storage, semiconductor devices capable of storing high-capacity data are desirable. As one of the methods of increasing data storage capacity of semiconductor devices, semiconductor devices including memory cells arranged three-dimensionally, instead of memory cells arranged two-dimensionally, have been under development. In addition, semiconductor devices, in which a portion of the semiconductor device is formed on a first substrate, another portion of the semiconductor device is formed on a second substrate, and the first substrate is bonded to the second substrate, have been under development.

### SUMMARY

According to embodiments of the present inventive concept, a semiconductor device includes: a peripheral circuit structure including a substrate and a circuit that is disposed on the substrate; a cell structure disposed on the peripheral circuit structure and including a plurality of gate electrodes and a channel that extends in a vertical direction through the gate electrodes; and a bonding structure located between the peripheral circuit structure and the cell structure, wherein the bonding structure includes: a first insulating layer attached to the peripheral circuit structure; a first bonding pad disposed on the peripheral circuit structure and electrically connected to the circuit of the peripheral circuit structure; a second insulating layer attached to the cell structure; a second bonding pad disposed on the cell structure and electrically connected to the plurality of gate electrodes; and an anisotropic conductive adhesive layer located between the first insulating layer and the second insulating layer and between the first bonding pad and the second bonding pad, and including a plurality of conductive particles.

According to embodiments of the present inventive concept, a semiconductor device includes: a peripheral circuit structure including a substrate and a circuit that is disposed on the substrate; a cell structure disposed on the peripheral circuit structure and including a plurality of gate electrodes and a channel that extends in a vertical direction through the gate electrodes; and a bonding structure located between the peripheral circuit structure and the cell structure, wherein the bonding structure includes: a first insulating layer attached to a first surface of the peripheral circuit structure and including a first opening; a first bonding pad disposed within the first opening of the first insulating layer and electrically connected to the circuit of the peripheral circuit structure; a second insulating layer attached to a first surface of the cell structure and including a second opening; a second bonding pad disposed within the second opening of the second insulating layer and electrically connected to the plurality of gate electrodes; and an anisotropic conductive adhesive layer located between the first insulating layer and the second insulating layer and between the first bonding pad and the second bonding pad, and including a plurality of conductive particles, wherein a portion of the first bonding pad is disposed outside of the first opening of the first insulating layer and protrudes in a direction toward the cell structure, and a portion of the second bonding pad is disposed outside of the second opening and protrudes in a direction toward the peripheral circuit structure.

According to embodiments of the present inventive concept, a semiconductor device includes: a peripheral circuit structure including a substrate and a circuit that is disposed on the substrate; a cell structure disposed on the peripheral circuit structure, wherein the cell structure includes a plurality of gate electrodes and a channel extending in a vertical direction through the plurality of gate electrodes, wherein the cell structure further includes a plurality of memory strings to which the channel is connected in the vertical direction; and a bonding structure located between the peripheral circuit structure and the cell structure, wherein the bonding structure includes: a first insulating layer attached to a first surface of the peripheral circuit structure and including a first opening; a first bonding pad disposed within the first opening of the first insulating layer and electrically connected to the circuit; a second insulating layer attached to a first surface of the cell structure and including a second opening; a second bonding pad disposed within the second opening of the second insulating layer and electrically connected to the plurality of gate electrodes; and an anisotropic conductive adhesive layer located between the first insulating layer and the second insulating layer and between the first bonding pad and the second bonding pad, and including a plurality of conductive particles, wherein the first insulating layer includes a first contact surface that is attached to the anisotropic conductive adhesive layer, the first bonding pad includes a first connection surface that is attached to the anisotropic conductive adhesive layer, the first connection surface of the first bonding pad protrudes in a direction toward the cell structure and beyond the first contact surface of the first insulating layer, the second insulating layer includes a second contact surface that is attached to the anisotropic conductive adhesive layer, the second bonding pad includes a second connection surface that is attached to the anisotropic conductive adhesive layer, and the second connection surface of the second bonding pad protrudes in a direction toward the peripheral circuit structure and beyond the second contact surface of the second insulating layer.

### BRIEF DESCRIPTION OF THE DRAWINGS

The above and other aspects of the present inventive concept will become more apparent by describing in detail embodiments thereof, with reference to the accompanying drawings, in which:

FIG. 1 is a block diagram of a semiconductor device according to embodiments of the present inventive concept;

FIG. 2 is a circuit diagram illustrating a memory block according to embodiments of the present inventive concept;

FIG. 3 is a perspective view illustrating a representative configuration of a semiconductor device according to embodiments of the present inventive concept;

FIG. 4 is a plan layout diagram of a semiconductor device according to embodiments of the present inventive concept;

FIG. 5 is a cross-sectional view taken along line A1-A1′ in FIG. 5;

FIG. 6 is an enlarged view of portion CX1 of FIG. 5;

FIG. 7 is an enlarged view of portion CX2 of FIG. 5;

FIG. 8 is a cross-sectional view of a semiconductor device according to embodiments of the present inventive concept;

FIG. 9 is a cross-sectional view of a semiconductor device according to embodiments of the present inventive concept;

FIG. 10 is a cross-sectional view of a semiconductor device according to embodiments of the present inventive concept;

FIG. 11 is a cross-sectional view of a semiconductor device according to embodiments of the present inventive concept;

FIGS. 12 to 15, 16A, 16B, 17A, 17B, 18, and 19 are schematic diagrams illustrating a method of manufacturing a semiconductor device, according to embodiments of the present inventive concept;

FIGS. 20A and 20B are cross-sectional views illustrating a method of manufacturing a semiconductor device, according to embodiments of the present inventive concept;

FIG. 21 is a diagram schematically illustrating a data storage system including a semiconductor device according to embodiments of the present inventive concept;

FIG. 22 is a perspective view schematically illustrating a data storage system including a semiconductor device according to embodiments of the present inventive concept; and

FIG. 23 is a cross-sectional view schematically illustrating semiconductor packages according to embodiments of the present inventive concept.

### DETAILED DESCRIPTION OF THE EMBODIMENTS

Hereinafter, embodiments of the present inventive concept are described in detail with reference to the accompanying drawings.

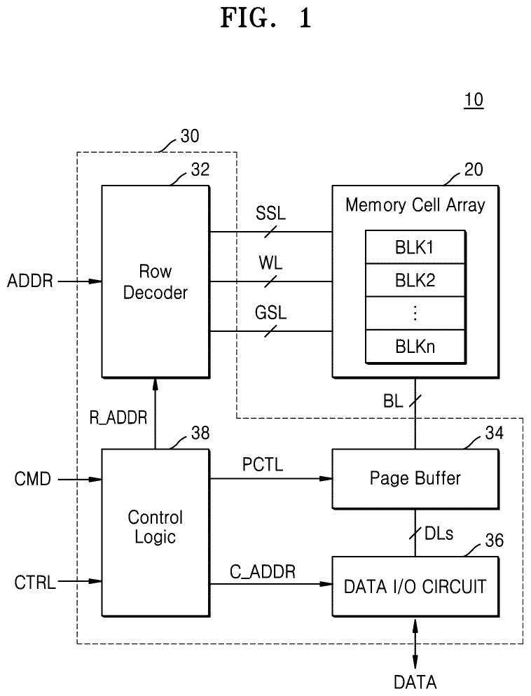

FIG. 1 is a block diagram of a semiconductor device 10 according to embodiments of the present inventive concept.

Referring to FIG. 1, the semiconductor device 10 may include a memory cell array 20 and a peripheral circuit 30. The memory cell array 20 includes a plurality of memory cell blocks BLK1, BLK2, . . . , BLKn. Each of the memory cell blocks BLK1, BLK2, . . . , BLKn may include a plurality of memory cells. The memory cell blocks BLK1, BLK2, . . . , BLKn may be connected to the peripheral circuit 30 through a bit line BL, a word line WL, a string select line SSL, and a ground select line GSL.

The peripheral circuit 30 may include a row decoder 32, a page buffer 34, a data input/output (I/O) circuit 36, and a control logic 38. In addition, the peripheral circuit 30 may further include, for example, an I/O interface, a column logic, a voltage generating unit, a pre-decoder, a temperature sensor, a command decoder, an address decoder, an amplifier circuit, and the like.

The memory cell array 20 may be connected to the page buffer 34 through the bit line BL and may be connected to the row decoder 32 through the word line WL, the string select line SSL, and the ground select line GSL. In the memory cell array 20, each of the memory cells that are included in the memory cell blocks BLK1, BLK2, . . . , BLKn may be a flash memory cell. The memory cell array 20 may include a 3D memory cell array. The 3D memory cell array may include a plurality of NAND strings, and each of the NAND strings may include a plurality of memory cells that are connected to a plurality of word lines WL that are vertically stacked on a substrate.

The peripheral circuit 30 may receive an address ADDR, a command CMD, and a control signal CTRL from the outside of the semiconductor device 10 and may transmit and receive data DATA to and from a device outside the semiconductor device 10.

In response to the address ADDR that is received from the outside, the row decoder 32 may select at least one of the memory cell blocks BLK1, BLK2, . . . , BLKn and may select a word line WL, a string select line SSL, and a ground select line GSL of the selected memory cell block. The row decoder 32 may transmit a voltage for performing a memory operation to the word line WL of the selected memory cell block.

The page buffer 34 may be connected to the memory cell array 20 through a bit line BL. During a program operation, the page buffer 34 may operate as a write driver to apply a voltage according to the data DATA to be stored in the memory cell array 20 through the bit line BL, and during a read operation, the page buffer 34 may operate as a sense amplifier to sense the data DATA that is stored in the memory cell array 20. The page buffer 34 may operate according to a control signal PCTL that is provided from the control logic 38.

The data I/O circuit 36 may be connected to the page buffer 34 through data lines DLs. During a program operation, the data I/O circuit 36 may receive the data DATA from a memory controller and provide program data DATA to the page buffer 34 based on the column address C_ADDR that is provided from the control logic 38. During a read operation, the data I/O circuit 36 transfers the read data DATA stored in the page buffer 34 to the memory controller based on the column address C_ADDR that is provided from the control logic 38.

The data I/O circuit 36 may transfer an input address or command to the control logic 38 or the row decoder 32. For example, the peripheral circuit 30 may further include an electrostatic discharge (ESD) circuit and a pull-up/pull-down driver.

The control logic 38 may receive the command CMD and the control signal CTRL from the memory controller. The control logic 38 may provide the row address R_ADDR to the row decoder 32 and the column address C_ADDR to the data I/O circuit 36. The control logic 38 may generate various internal control signals used in the semiconductor device 10 in response to the control signal CTRL. For example, the control logic 38 may adjust a voltage level that is provided to the word line WL and the bit line BL when a memory operation, such as a program operation or an erase operation, is performed.

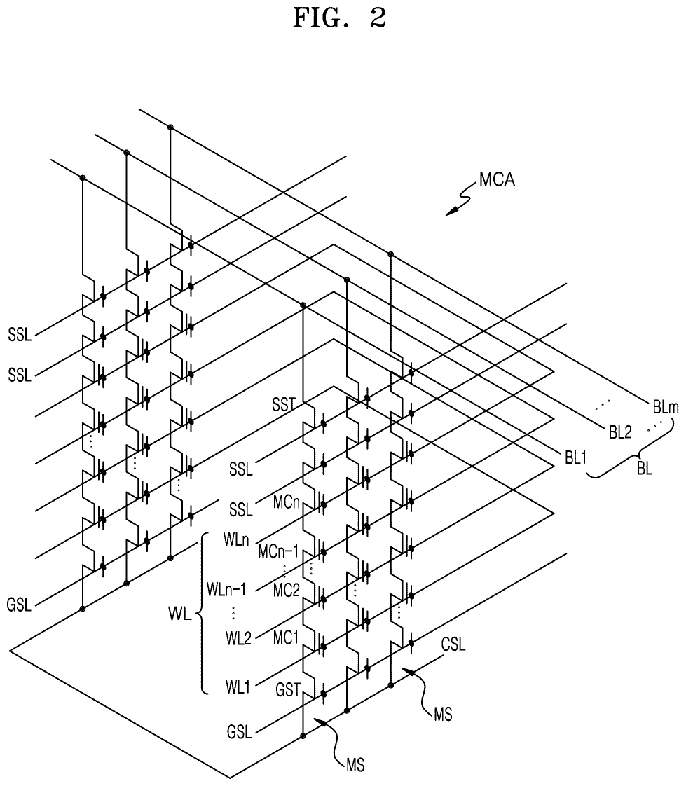

FIG. 2 is a circuit diagram of a memory block according to embodiments of the present inventive concept.

Referring to FIG. 2, the memory cell array MCA may include a plurality of memory cell strings MS. The memory cell array MCA may include a plurality of bit lines BL: BL1, BL2, . . . , BLm, a plurality of word lines WL: WL1, WL2, . . . , WLn−1, WLn, at least one string select line SSL, at least one ground select line GSL, and a common source line CSL. The memory cell strings MS may be formed between the bit lines BL: BL1, BL2, . . . , BLm and the common source line CSL. Although FIG. 2 illustrates a case in which each of the memory cell strings MS includes two string select lines SSL, the present inventive concept is not limited thereto. For example, each of the memory cell strings MS may include one string select line SSL.

Each of the memory cell strings MS may include a string select transistor SST, a ground select transistor GST, and a plurality of memory cell transistors MC1, MC2, . . . , MCn−1, MCn. A drain region of the string select transistor SST may be connected to the bit line BL: BL1, BL2, . . . , BLm, and a source region of the ground select transistor GST may be connected to the common source line CSL. The common source line CSL may be a region to which source regions of the ground select transistors GST are connected in common.

The string select transistor SST may be connected to the string select line SSL, and the ground select transistor GST may be connected to the ground select line GSL. The memory cell transistors MC1, MC2, . . . , MCn−1, MCn may be connected to the plurality of word lines WL: WL1, WL2, . . . , WLn−1, WLn, respectively.

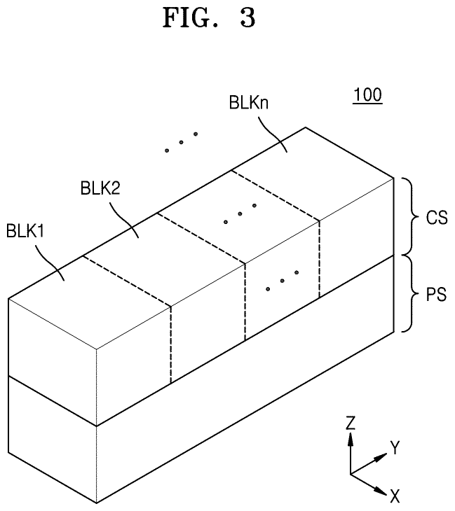

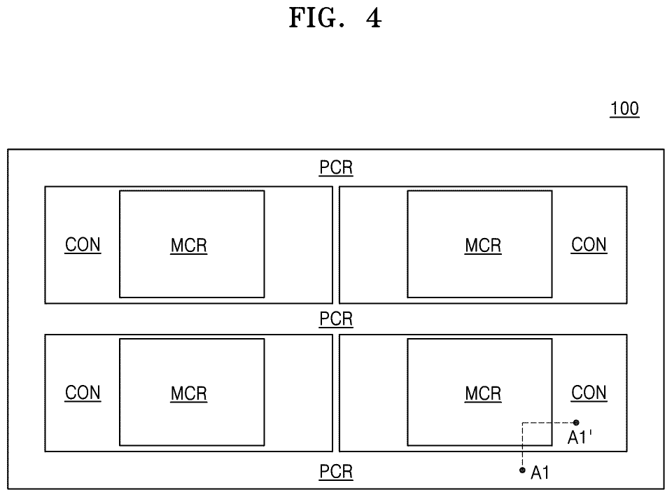

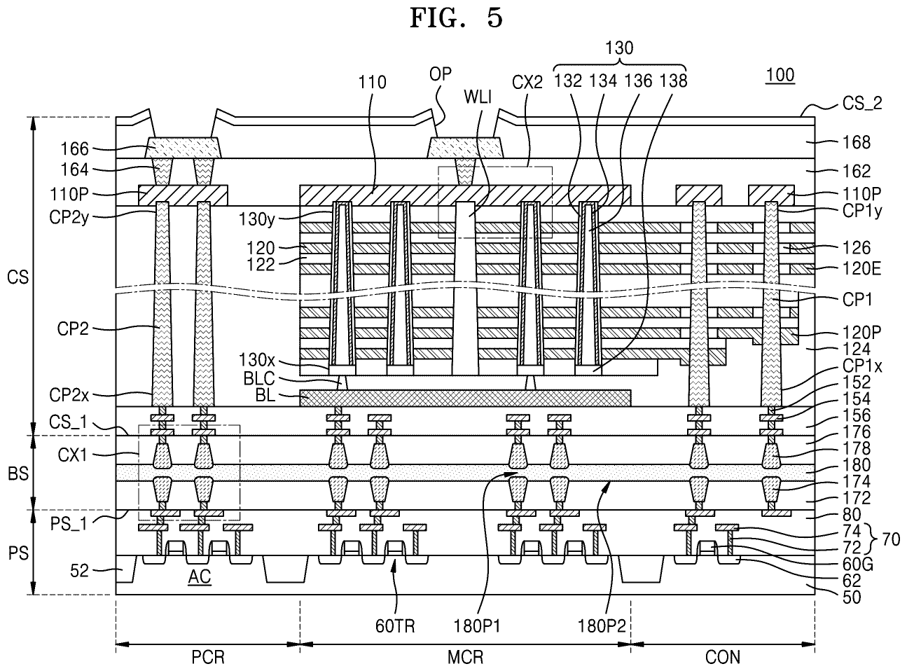

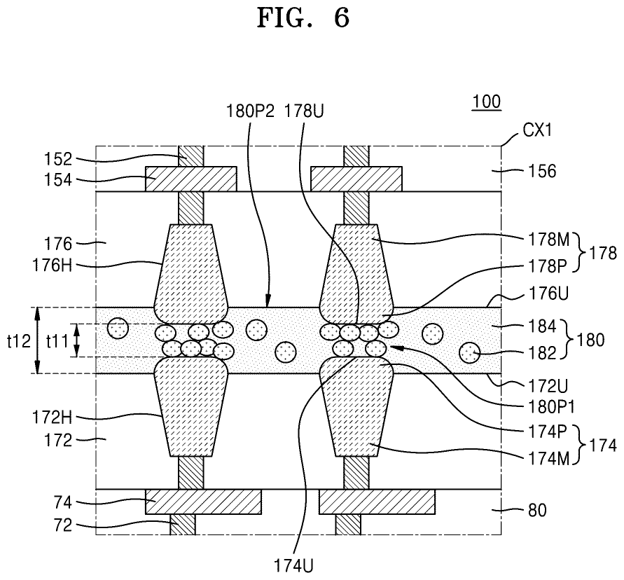

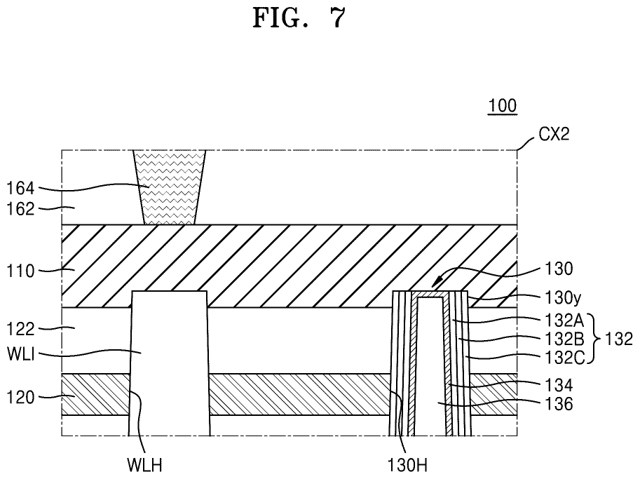

FIG. 3 is a perspective view illustrating a representative configuration of a semiconductor device 100 according to embodiments of the present inventive concept. FIG. 4 is a plan layout view of the semiconductor device 100 according to embodiments of the present inventive concept, and FIG. 5 is a cross-sectional view taken along line A1-A1′ of FIG. 5. FIG. 6 is an enlarged view of portion CX1 of FIG. 5, and FIG. 7 is an enlarged view of portion CX2 of FIG. 5.

Referring to FIGS. 3 to 7, the semiconductor device 100 includes a cell structure CS, a peripheral circuit structure PS, and a bonding structure BS. The cell structure CS and the peripheral circuit structure PS overlap each other in a vertical direction Z, and the bonding structure BS is located between the cell structure CS and the peripheral circuit structure PS. The cell structure CS may include the memory cell array 20 described above with reference to FIG. 1, and the peripheral circuit structure PS may include the peripheral circuit 30 described above with reference to FIG. 1. The bonding structure BS may be located between the cell structure CS and the peripheral circuit structure PS to attach the cell structure CS to the peripheral circuit structure PS.

The cell structure CS may include a plurality of memory cell blocks BLK1, BLK2, . . . , BLKn. Each of the memory cell blocks BLK1, BLK2, . . . , BLKn may include three-dimensionally arranged memory cells.

The peripheral circuit structure PS may include a peripheral circuit transistor 60TR and a peripheral circuit interconnection structure 70 disposed on a substrate 50. An active region AC may be provided on the substrate 50 by a device isolation layer 52, and a plurality of peripheral circuit transistors 60TR may be formed on the active region AC. The peripheral circuit transistors 60TR may each include a peripheral circuit gate 60G and source/drain regions 62 that are located in portions of the substrate 50 on both sides of the peripheral circuit gate 60G.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or an epitaxial layer. In an embodiment of the present inventive concept, the substrate 50 may include a silicon-on-insulator (SOI) substrate or a germanium-on-insulator (GeOI) substrate.

The peripheral circuit interconnection structure 70 includes a plurality of peripheral circuit contacts 72 and a plurality of peripheral circuit interconnection layers 74. An interlayer insulating layer 80 covering the peripheral circuit transistor 60TR and the peripheral circuit interconnection structure 70 may be disposed on the substrate 50. The peripheral circuit interconnection layers 74 may be a multilayer structure including a plurality of metal layers at different vertical levels from each other. The peripheral circuit structure PS may refer to a first surface PS_1 disposed toward the cell structure CS, and the first surface PS_1 may refer to a surface opposite to a bottom surface of the substrate 50 and may refer to the uppermost surface of the peripheral circuit interconnection structure 70.

The cell structure CS may include a cell region MCR, a connection region CON, and a peripheral circuit connection region PCR. The cell region MCR may be a region in which the memory cell block BLK including the memory cell strings MS extending in the vertical direction Z is located. In the cell region MCR, a common source layer 110, a plurality of gate electrodes 120, and a channel 130 extending in the vertical direction Z through the gate electrodes 120 and connected to the common source layer 110 may be located. In the connection region CON, an extension 120E and a pad portion 120P are connected to the gate electrodes 120, and a first plug CP1 electrically connects the pad portion 120P by means of the extension 120E. In the peripheral circuit connection region PCR, a second plug CP2 extends in the vertical direction Z and is electrically connected to the peripheral circuit interconnection structure 70.

The cell structure CS may include a first surface CS_1 connected to the peripheral circuit structure PS and a second surface CS_2 opposite to the first surface CS_1. In the diagram, the first surface CS_1 of the cell structure CS is shown to be disposed on a lower side of the cell structure CS and the second surface CS_2 of the cell structure CS is shown to be disposed on an upper side of the cell structure CS. Here, for convenience, as shown in the diagram, being disposed close to the first surface CS_1 of the cell structure CS is referred to as being disposed at a lower vertical level, and being disposed close to the second surface CS_2 of the cell structure CS is referred to as being disposed at a higher vertical level.

The gate electrodes 120 may be arranged to be apart from each other in the vertical direction Z in the cell region MCR, and the gate electrodes 120 may be arranged alternately with mold insulating layers 122. The gate electrodes 120 may extend to the connection region CON, and portions of the gate electrodes 120 arranged in the connection region CON may be referred to as extensions 120E. The extensions 120E may have a horizontal length that gradually increases in a direction toward the second surface CS_2 of the cell structure CS (that is, in an upward direction in the diagram). The extensions 120E may have a step shape, and pad portions 120P may be connected to ends of the extensions 120E. The pad portions 120P may have a greater thickness in the vertical direction Z than that of the extensions 120E.

In embodiments of the present inventive concept, the gate electrodes 120 may correspond to at least one ground select line GSL, word lines WL: WL1, WL2, . . . , WLn−1, and WLn, and at least one string select line SSL. For example, the uppermost one of the gate electrodes 120 may function as a ground select line GSL, two lowermost ones of the gate electrodes 120 may function as string select lines SSL, and the other gate electrodes 120 may function as word lines WL. Accordingly, a memory cell string MS including the ground selection transistor GST, the string selection transistor SST, and the memory cell transistors MC1, MC2, . . . , MCn−1, MCn connected in series therebetween may be provided. In embodiments of the present inventive concept, at least one of the gate electrodes 120 may function as a dummy word line, but the present inventive concept is not limited thereto.

A stack isolation insulating layer WL1 may be located in a stack separation opening WLH extending in the vertical direction Z through the gate electrodes 120 and the mold insulating layers 122. The stack isolation insulating layer WL1 may have an upper surface on a vertical level that is higher than that of the uppermost gate electrode 120 and may protrude upwardly in the vertical direction Z beyond the uppermost gate electrode 120. The gate electrodes 120 located between a pair of gate stack isolation openings WLH may form one block BLK.

A stack insulating layer 124 may be disposed to at least partially surround the gate electrodes 120, the extensions 120E, and the pad portions 120P in the connection region CON and the peripheral circuit connection region PCR. In a plan view, the stack insulating layer 124 may be located to at least partially surround the gate electrodes 120 and may have an upper surface on the same level as that of the uppermost gate electrode 120 in the peripheral circuit connection region PCR.

The channel 130 may include a first end 130x disposed to be close to the peripheral circuit structure PS and a second end 130y that is opposite to the first end 130x. In embodiments of the present inventive concept, the channel 130 may have inclined sidewalls such that a width of the first end 130x is greater than a width of the second end 130y. The bit line BL may be electrically connected to the first end 130x of the channel 130 through a bit line contact BLC, and the common source layer 110 may be connected to the second end 130y of the channel 130.

The channel 130 may be located in a channel hole 130H that extends in the vertical direction Z through the gate electrodes 120 and the mold insulating layers 122 and may include a gate insulating layer 132, a channel layer 134, a buried insulating layer 136, and a drain region 138. The channel layer 134 may have a cylindrical shape or a polygonal shape, and the gate insulating layer 132 may be disposed on an outer wall of the channel layer 134. The buried insulating layer 136 may be disposed on an inner wall of the channel layer 134. The gate insulating layer 132 might not be disposed on the uppermost surface of the channel layer 134, for example, on an upper surface of the channel layer 134 that is disposed at the second end 130y of the channel 130.

As shown in FIG. 7, the gate insulating layer 132 may have a structure including a tunneling dielectric layer 132A, a charge storage layer 132B, and a blocking dielectric layer 132C sequentially disposed on the outer wall of the channel layer 134. Relative thicknesses of the tunneling dielectric layer 132A, the charge storage layer 132B, and the blocking dielectric layer 132C, which form the gate insulating layer 132, are not limited to those illustrated in FIG. 7 and may be variously modified.

The tunneling dielectric layer 132A may include, for example, silicon oxide, hafnium oxide, aluminum oxide, zirconium oxide, tantalum oxide, or the like. The charge storage layer 132B may be a region in which electrons passing through the tunneling dielectric layer 132A from the channel layer 134 may be stored and may include, for example, silicon nitride, boron nitride, silicon boron nitride, or polysilicon doped with impurities. The blocking dielectric layer 132C may include, for example, silicon oxide, silicon nitride, or a metal oxide having a dielectric constant higher than that of silicon oxide. The metal oxide may include, for example, hafnium oxide, aluminum oxide, zirconium oxide, tantalum oxide, or combinations thereof.

The common source layer 110 may be connected to the second end 130y of the channel 130 and may be conformally formed to cover an upper surface of the stack isolation insulating layer WL1. In a plan view, the common source layer 110 may be disposed on the cell region MCR. For example, the common source layer 110 may be disposed on the entire cell region MCR.

In the connection region CON, a first plug CP1 may be disposed through the extensions 120E and the pad portions 120P that extend from the gate electrodes 120. Insulating patterns 126 may be formed at a position vertically overlapping the pad portion 120P connected to the first plug CP1, and insulating patterns 126 may be formed between the first plug CP1 and the extensions 120E. In embodiments of the present inventive concept, the first end CP1x of the first plug CP1 may be disposed to be adjacent to the peripheral circuit structure PS, and the second end CPly of the first plug CP1 may be disposed to be opposite to the first end CP1x. The first plug CP1 may have an inclined sidewall so that a width of the first end CP1x is greater than a width of the second end CPly. The second end CPly of the first plug CP1 may be covered by an extension 110P of the common source layer 110.

In embodiments of the present inventive concept, the first plug CP1 may include a metal, such as tungsten, nickel, cobalt, and tantalum, a metal silicide, such as tungsten silicide, nickel silicide, cobalt silicide, and tantalum silicide, doped polysilicon, titanium nitride, tantalum nitride, tungsten nitride, or combinations thereof.

In the peripheral circuit connection region PCR, the second plug CP2 may be disposed to penetrate the stack insulating layer 124. A first end CP2x of the second plug CP2 may be disposed to be adjacent to the peripheral circuit structure PS or the bonding structure BS, and a second end CP2y of the second plug CP2 may be disposed to be opposite to the first end CP2x. The second plug CP2 may have an inclined sidewall so that a width of the first end CP2x is greater than a width of the second end CP2y.

A connection via 152, an interconnection layer 154, and an interlayer insulating film 156 surrounding the connection via 152 and the interconnection layer 154 may be located between the stack insulating layer 124 and the bonding structure BS. The connection via 152 and the interconnection layer 154 may include multiple layers arranged at a plurality of vertical levels that are different from each other. The connection via 152 and the interconnection layer 154 may electrically connect the bit line BL, the first plug CP1, and the second plug CP2 to the peripheral circuit structure PS through the bonding structure BS.

An upper interlayer insulating film 162 may be disposed on the common source layer 110, rear vias 164 may be disposed through the upper interlayer insulating film 162, and rear pads 166 may be disposed on the upper interlayer insulating film 162. At least one of the rear vias 164 may be disposed to be connected to an upper surface of the common source layer 110 through the upper interlayer insulating film 162 in the cell region MCR, and at least another of the rear vias 164 may be connected to the extension 110P of the common source layer 110 through the upper interlayer insulating film 162 in the peripheral circuit connection region PCR. The rear pads 166 may be connected to the rear vias 164. A passivation layer 168 may be disposed on the upper interlayer insulating film 162, and an opening OP of the passivation layer 168 may expose upper surfaces of the rear pads 166.

The bonding structure BS may be located between a first surface PS_1 of the peripheral circuit structure PS and the first surface CS_1 of the cell structure CS and may be located to vertically overlap the cell region MCR, the connection region CON, and the peripheral circuit connection region PCR of the cell structure CS. For example, the bonding structure BS may be located to vertically overlap all of the cell region MCR, the connection region CON, and the peripheral circuit connection region PCR of the cell structure CS. The bonding structure BS may include a first insulating layer 172, a first bonding pad 174, a second insulating layer 176, a second bonding pad 178, and an anisotropic conductive adhesive layer 180.

The first insulating layer 172 may be disposed on the first surface PS_1 of the peripheral circuit structure PS, for example, on an upper surface of the interlayer insulating film 80. In embodiments of the present inventive concept, the first insulating layer 172 may include at least one of silicon carbon nitride, silicon nitride, silicon oxynitride, silicon oxide, and/or a low-k dielectric material. The first insulating layer 172 may include a first opening 172H.

The first insulating layer 172 may include a first contact surface 172U that is in contact with and/or attached to the anisotropic conductive adhesive layer 180. For example, the first contact surface 172U of the first insulating layer 172 may refer to a surface of the first insulating layer 172 in the upward direction in FIG. 6 and may refer to a surface of the first insulating layer 172 disposed to be relatively close to the cell structure CS.

The first bonding pad 174 may be disposed within the first opening 172H of the first insulating layer 172. The first bonding pad 174 may be electrically connected to the peripheral circuit interconnection layer 74 of the peripheral circuit structure PS. For example, the first bonding pad 174 may be electrically connected to a peripheral circuit transistor 60TR through the peripheral circuit interconnection layer 74 of the peripheral circuit structure PS.

In embodiments of the present inventive concept, the first bonding pad 174 may include copper, nickel, aluminum, gold, tungsten, or alloys thereof. For example, a barrier metal film including titanium, tantalum, titanium nitride, tantalum nitride, or combinations thereof may be disposed on at least a portion of the first bonding pad 174.

The first bonding pad 174 may include a first connection surface 174U that is in contact with or attached to the anisotropic conductive adhesive layer 180. For example, a first connection surface 174U of the first bonding pad 174 may refer to a surface of the first bonding pad 174 in an upward direction in FIG. 6 and may refer to a surface of the first bonding pad 174 disposed to face the cell structure CS.

In embodiments of the present inventive concept, the first connection surface 174U of the first bonding pad 174 may protrude, relative to the first contact surface 172U of the first insulating layer 172. For example, the first connection surface 174U may be disposed higher than the first contact surface 172U. For example, the first bonding pad 174 may protrude beyond the first contact surface 172U. For example, the first connection surface 174U of the first bonding pad 174 may protrude in a direction toward the cell structure CS (e.g., outward or upward) with respect to the first contact surface 172U of the first insulating layer 172. In embodiments of the present inventive concept, at least a portion of the first connection surface 174U of the first bonding pad 174 may have a rounded upper surface or a rounded shape.

In embodiments of the present inventive concept, the first bonding pad 174 may include a first main region 174M and a first protruding region 174P. The first main region 174M may be disposed within the first opening 172H of the first insulating layer 172, and the first protruding region 174P may be integrally connected to the first main region 174M on the first main region 174M and may be disposed outside the first opening 172H. For example, the first protruding region 174P may refer to a portion disposed at a vertical level higher than that of the first contact surface 172U of the first insulating layer 172. For example, the first protruding region 174P may protrude in a direction toward the cell structure CS with respect to the first contact surface 172U of the first insulating layer 172. In addition, the first protruding region 174P may contact the anisotropic conductive adhesive layer 180, and an upper surface of the first protruding region 174P may include the first connection surface 174U.

The second insulating layer 176 may be disposed on the first surface CS_1 of the cell structure CS, for example, on a bottom surface of the interlayer insulating film 156 (e.g., on a surface of the interlayer insulating film 156 disposed facing the peripheral circuit structure PS in FIG. 6). In embodiments of the present inventive concept, the second insulating layer 176 may include at least one of silicon carbon nitride, silicon nitride, silicon oxynitride, silicon oxide, and/or a low-k dielectric material. The second insulating layer 176 may include a second opening 176H.

The second insulating layer 176 may include a second contact surface 176U that is in contact with or attached to the anisotropic conductive adhesive layer 180. For example, the second contact surface 176U of the second insulating layer 176 may refer to a surface of the second insulating layer 176 in a downward direction in FIG. 6 and may refer to a surface of the second insulating layer 176 disposed to be facing the peripheral circuit structure PS.

The second bonding pad 178 may be disposed within the second opening 176H of the second insulating layer 176. The second bonding pad 178 may be electrically connected to the connection via 152 and/or the interconnection layer 154 of the cell structure CS. For example, the second bonding pad 178 may be electrically connected to the bit line BL of the cell structure CS through the connection via 152 and/or the interconnection layer 154, or the second bonding pad 178 may be electrically connected to the first plug CP1 and the second plug CP2 of the cell structure CS, for example, the gate electrodes 120 of the cell structure CS, through the connection via 152 and/or the interconnection layer 154.

In embodiments of the present inventive concept, the second bonding pad 178 may include copper, nickel, aluminum, gold, tungsten, or alloys thereof. For example, a barrier metal film including titanium, tantalum, titanium nitride, tantalum nitride, or combinations thereof may be further disposed on at least a portion of the second bonding pad 178.

The second bonding pad 178 may include a second connection surface 178U that is in contact with and/or attached to the anisotropic conductive adhesive layer 180. For example, the second connection surface 178U of the second bonding pad 178 may refer to a surface of the second bonding pad 178 in a downward direction in FIG. 6 and may face the peripheral circuit structure PS. For example, the second connection surface 178U may refer to a surface of the second bonding pad 178 that is disposed to be closer to the peripheral circuit structure PS when compared to another surface of the second bonding pad 178 that is opposite to the second connection surface 178U.

In embodiments of the present inventive concept, the second connection surface 178U of the second bonding pad 178 may protrude downwardly, relative to the second contact surface 176U of the second insulating layer 176. For example, the second contact surface 178U of the second bonding pad 178 may protrude in a direction toward the peripheral circuit structure PS (e.g., outward or downward) with respect to the second contact surface 176U of the second insulating layer 176. In embodiments of the present inventive concept, at least a portion of the second connection surface 178U of the second bonding pad 178 may have a rounded upper surface or a rounded shape.

In embodiments of the present inventive concept, the second bonding pad 178 may include a second main region 178M and a second protruding region 178P. The second main region 178M may be disposed within the second opening 176H of the second insulating layer 176, and the second protruding region 178P may be integrally connected to the second main region 178M on the second main region 178M and may be disposed outside the second opening 176H. For example, the second protruding region 178P may refer to a portion that is disposed at a vertical level lower than that of the second contact surface 176U of the second insulating layer 176. For example, the second protruding region 178P may protrude in a direction toward the peripheral circuit structure PS with respect to the second contact surface 176U of the second insulating layer 176. In addition, the second protruding region 178P may contact the anisotropic conductive adhesive layer 180, and the surface of the second protruding region 178P may include a second connection surface 178U.

The anisotropic conductive adhesive layer 180 may be located between the first insulating layer 172 and the second insulating layer 176 and between the first bonding pad 174 and the second bonding pad 178. As the anisotropic conductive adhesive layer 180 is located between the first insulating layer 172 and the second insulating layer 176 and between the first bonding pad 174 and the second bonding pad 178, the first insulating layer 172 might not be in direct contact with the second insulating layer 176 and the first bonding pad 174 might not be in direct contact with the second bonding pad 178.

The anisotropic conductive adhesive layer 180 may include a plurality of conductive particles 182 and an adhesive member 184, and the conductive particles 182 may be dispersed and disposed within the adhesive member 184. In embodiments of the present inventive concept, the conductive particles 182 may include at least one of gold, silver, copper, nickel, aluminum, zinc, tin, lead, indium, and/or palladium. The adhesive member 184 may include at least one of epoxy resin, styrene resin, silicone resin, acrylic resin, polyolefin resin, melamine resin, urethane resin, phenol resin, polyester resin, nitrile rubber, and/or styrene-butadiene rubber.

The anisotropic conductive adhesive layer 180 may include a first portion 180P1 and a second portion 180P2. The first portion 180P1 may refer to a portion of the anisotropic conductive adhesive layer 180 that is located between the first bonding pad 174 and the second bonding pad 178, and the second portion 180P2 may refer to a portion of the anisotropic conductive adhesive layer 180 that is located between the first insulating layer 172 and the second insulating layer 176. For example, the first portion 180P1 may directly contact the first bonding pad 174 and the second bonding pad 178, and the second portion 180P2 may directly contact the first insulating layer 172 and the second insulating layer 176.

The conductive particles 182 that are located in the first portion 180P1 of the anisotropic conductive adhesive layer 180 may contact at least one of the first bonding pad 174 and/or the second bonding pad 178 and may be located between the first bonding pad 174 and the second bonding pad 178. In addition, the conductive particles 182 may contact each other and be connected to each other between the first bonding pad 174 and the second bonding pad 178 to form an electrical connection path in a space between the first bonding pad 174 and the second bonding pad 178. For example, the first bonding pad 174 might not be in direct contact the second bonding pad 178 but may be electrically connected to the second bonding pad 178 through the conductive particles 182 that are located in the first portion 180P1 of the anisotropic conductive adhesive layer 180.

In embodiments of the present inventive concept, the first portion 180P1 of the anisotropic conductive adhesive layer 180 may have a first thickness t11 in the vertical direction, and the second portion 180P2 of the anisotropic conductive adhesive layer 180 may have a thickness t12 in the vertical direction. The second thickness t12 may be greater than the first thickness t11. For example, the first thickness t11 of the first portion 180P1 of the anisotropic conductive adhesive layer 180 may correspond to a distance between the first connection surface 174U of the first bonding pad 174 and the second connection surface 178U of the second bonding pad 178. In addition, the second thickness t12 of the second portion 180P2 of the anisotropic conductive adhesive layer 180 may correspond to a distance between the first contact surface 172U of the first insulating layer 172 and the second contact surface 176U of the second insulating layer 176. In embodiments of the present inventive concept, the distance between the first connection surface 174U of the first bonding pad 174 and the second connection surface 178U of the second bonding pad 178 may be less than the distance between the first contact surface 172U of the first insulating layer 172 and the second contact surface 176U of the second insulating layer 176.

In embodiments of the present inventive concept, in the process of positioning the anisotropic conductive adhesive layer 180 between the cell structure CS and the peripheral circuit structure PS and attaching the cell structure CS to the peripheral circuit structure PS through the anisotropic conductive adhesive layer 180, the first portion 180P1 of the anisotropic conductive adhesive layer 180, which is located between the first protruding region 174P of the first bonding pad 174 and the second protruding region 178P of the second bonding pad 178, may be subjected to compression or a pressing force, and accordingly, the conductive particles 182 disposed within the first portion 180P1 of the anisotropic conductive adhesive layer 180 may come into contact with at least one of the first protruding region 174P of the first bonding pad 174 and/or the second protruding region 178P of the second bonding pad 178, or the conductive particles 182 disposed in the first portion 180P1 of the anisotropic conductive adhesive layer 180 may be aggregated and compressed to be connected between the first protruding region 174P of the first bonding pad 174 and the second protruding region 178P of the second bonding pad 178.

In other words, the anisotropic conductive adhesive layer 180 may be electrically connected in a thickness direction (e.g., the vertical direction) of the anisotropic conductive adhesive layer 180 and may be electrically insulated in a width direction (e.g., the horizontal direction) of the anisotropic conductive adhesive layer 180, and accordingly, the first portion 180P1 of the anisotropic conductive adhesive layer 180 may function as an electrical connection-providing portion between the first bonding pad 174 and the second bonding pad 178, and the second portion 180P2 of the anisotropic conductive adhesive layer 180 may function as a physical attachment-providing portion between the peripheral circuit structure PS and the cell structure CS. For example, even when the first bonding pads 174 are arranged with a relatively small width and pitch and the second bonding pads 178 are arranged with a relatively small width and pitch, a reliable electrical connection may be implemented between the first bonding pad 174 and the second bonding pad 178 through the anisotropic conductive adhesive layer 180.

According to a comparative example, in a structure in which the peripheral circuit structure is attached to the cell structure by using a bonding method, a metal-insulating layer hybrid bonding method is used in which the upper bonding insulating layer directly contacts the lower bonding insulating layer, and the upper bonding pad directly contacts the lower bonding pad. However, because the thermal expansion characteristics and/or etching characteristics of the lower and upper bonding pads are different from those of the lower and upper bonding insulating layers, a process of adjusting heights of the lower and upper bonding pads to form a flat bonding interface has a high level of difficulty. For example, if the height of the bonding pad is too small or a void is formed within the bonding pad, sufficient electrical connection might not be provided, and if the height of the bonding pad is too large, delamination of the bonding insulating layer may occur and sufficient mechanical/physical attachment might not be provided.

However, according to the embodiments described above, the cell structure CS may be attached to the peripheral circuit structure PS through the anisotropic conductive adhesive layer 180, and accordingly, a reliable electrical connection and/or mechanical attachment between the cell structure CS and the peripheral circuit structure PS may be implemented through the anisotropic conductive adhesive layer 180 even when the width and pitch of the first and second bonding pads 174 and 178 are small. In addition, the difficulty of the process of forming the first and second bonding pads 174 and 178 may decrease.

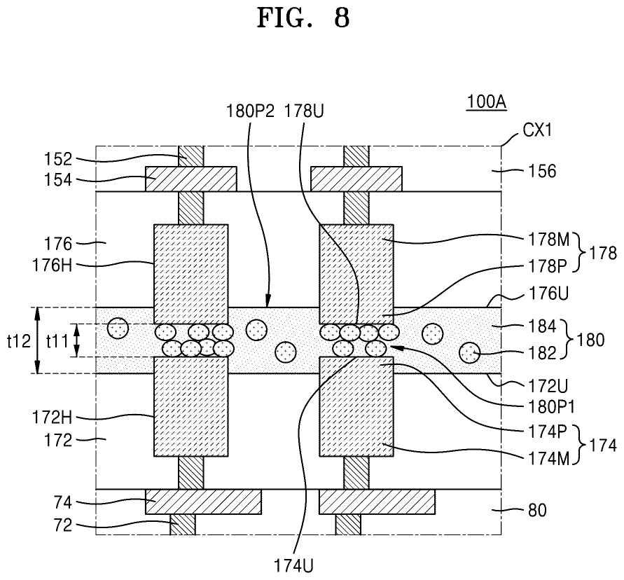

FIG. 8 is a cross-sectional view of a semiconductor device 100A according to embodiments of the present inventive concept.

Referring to FIG. 8, the first connection surface 174U of the first bonding pad 174 may protrude upwardly with respect to the first contact surface 172U of the first insulating layer 172, and the first connection surface 174U of the first bonding pad 174 may include a flat surface. The second connection surface 178U of the second bonding pad 178 may protrude downwardly with respect to the second contact surface 176U of the second insulating layer 176, and the second connection surface 178U of the second bonding pad 178 may include a flat surface. In embodiments of the present inventive concept, the first opening 172H of first insulating layer 172 may have a substantially vertical sidewall profile and the second opening 174H of second insulating layer 174 may have a substantially vertical sidewall profile.

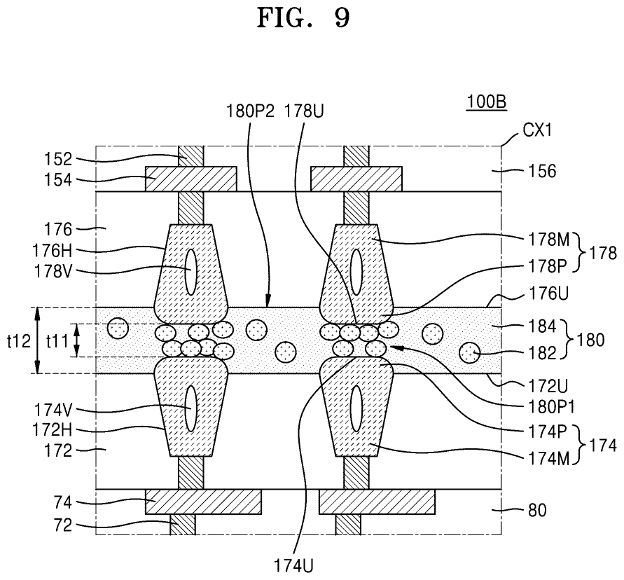

FIG. 9 is a cross-sectional view of a semiconductor device 100B according to embodiments of the present inventive concept.

Referring to FIG. 9, a first void 174V may be located in a first main region 174M of the first bonding pad 174. In an operation of forming the first main region 174M inside the first opening 172H of the first insulating layer 172 by a plating process or the like or in an operation of expanding the volume of the first main region 174M at high temperatures after forming the first main region 174M, the first void 174V, which is a space that is not filled with metal atoms, such as copper, may be formed inside the first main region 174M. No voids or seams are located in the first protruding region 174P of the first bonding pad 174, and the inside of the first protruding region 174P may be completely filled with a metal material.

In embodiments of the present inventive concept, after the first void 174V is formed inside the first main region 174M in the operation of forming the first main region 174M or expanding the volume of the first main region 174M, the first protruding region 174P may be formed on an upper surface of the first main region 174M by an additional plating process, and accordingly, the first void 174V may be formed inside the first main region 174M and might not be formed inside the first protruding region 174P. For example, the first void 174V may be covered by the first protruding region 174P and might not be in direct contact with the anisotropic conductive adhesive layer 180.

In embodiments of the present inventive concept, a second void 178V may be disposed within a second main region 178M of the second bonding pad 178. In an operation of forming the second main region 178M inside the second opening 176H of the second insulating layer 176 by a plating process or the like or in an operation of expanding the volume of the second main region 178M at high temperatures after forming the second main region 178M, the second void 178V, which is a space that is not filled with metal atoms, such as copper, may be formed inside the second main region 178M. No voids or seams are located in the second protruding region 178P of the second bonding pad 178, and the inside of the second protruding region 178P may be completely filled with a metal material.

In embodiments of the present inventive concept, after the second void 178V is formed inside the second main region 178M in the operation of forming the second main region 178M or expanding the volume of the second main region 178M, the second protruding region 178P may be formed on an upper surface of the second main region 178M by an additional plating process, and accordingly, the second void 178V may be formed inside the second main region 178M and might not be formed inside the second protruding region 178P. For example, the second void 178V may be covered by the second protruding region 178P and might not be in direct contact with the anisotropic conductive adhesive layer 180.

In general, in a comparative example of forming a cell structure and a peripheral circuit structure using a metal-insulating layer hybrid bonding method, in which the upper bonding insulating layer is in direct contact with the lower bonding insulating layer and the upper bonding pad is in direct contact with the lower bonding pad, a void may be formed inside the upper bonding pad and/or lower bonding pad in a process of forming the upper bonding pad and/or lower bonding pad or in a process of expanding the volume of the upper bonding pad and/or lower bonding pad. In this case, sufficient electrical connection might not be provided between the upper and lower bonding pads by the void.

However, according to the above-described embodiments, the cell structure CS may be attached to the peripheral circuit structure PS through the anisotropic conductive adhesive layer 180, and accordingly, even if the first void 174V is formed inside the first bonding pad 174, the first void 174V may be covered by the first protruding region 174P and might not directly contact the anisotropic conductive adhesive layer 180. In addition, even if the second void 178V is formed in the second bonding pad 178, the second void 178V may be covered by the second protruding region 178P and might not directly contact the anisotropic conductive adhesive layer 180. A reliable electrical connection and/or mechanical attachment between the cell structure CS and the peripheral circuit structure PS may be implemented through the anisotropic conductive adhesive layer 180, and the difficulty of the process of forming the first and second bonding pads 174 and 178 may decrease.

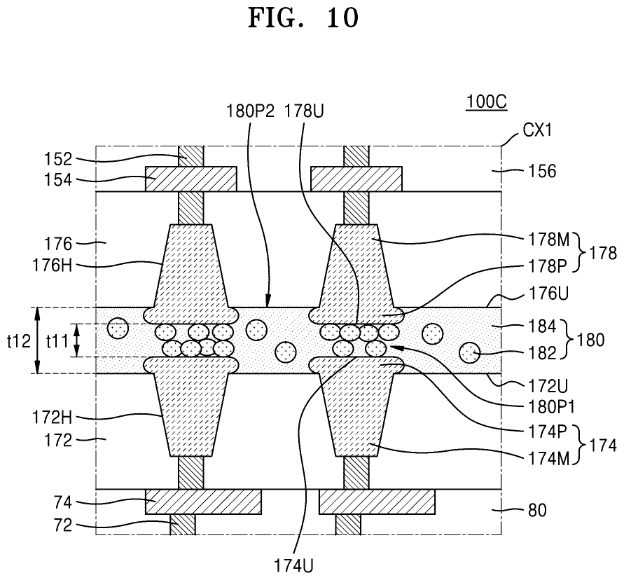

FIG. 10 is a cross-sectional view of a semiconductor device 100C according to embodiments of the present inventive concept.

Referring to FIG. 10, a horizontal width of the first protruding region 174P may be greater than a horizontal width of the first main region 174M of the first bonding pad 174. For example, after the first main region 174M is formed inside the first opening 172H of the first insulating layer 172 by a plating process, etc., the first protruding region 174P may be formed on the upper surface of the first main region 174M by an additional plating process, and when the first protruding region 174P extends and overgrows to the outside of the first opening 172H of the first insulating layer 172, the horizontal width of the first protruding region 174P may be greater than the horizontal width of the first main region 174M. For example, the first protruding region 174P may extend and overgrow in a direction that is parallel to the first contact surface 172U of the first insulating layer 172.

In embodiments of the present inventive concept, a horizontal width of the second protruding region 178P may be greater than a horizontal width of the second main region 178M of the second bonding pad 178. For example, after the second main region 178M is formed inside the second opening 174H of the second insulating layer 174 by a plating process, etc., the second protruding region 178P may be formed on the upper surface of the second main region 178M by an additional plating process, and when the second protruding region 178P extends and overgrows to the outside of the second opening 176H of the second insulating layer 176, the horizontal width of the second protruding region 178P may be greater than the horizontal width of the second main region 178M. For example, the second protruding region 178P may extend and overgrow in a direction that is parallel to the second contact surface 176U of the second insulating layer 176.

According to embodiments of the present inventive concept, because the first protruding region 174P may be formed by an additional plating process after the first main region 174M is formed and the second protruding region 178P may be formed by an additional plating process after the second main region 178M is formed, a sufficient electrical connection may be secured between the first protruding region 174P and the second protruding region 178P2 through the first portion 180P1 of the anisotropic conductive adhesive layer 180.

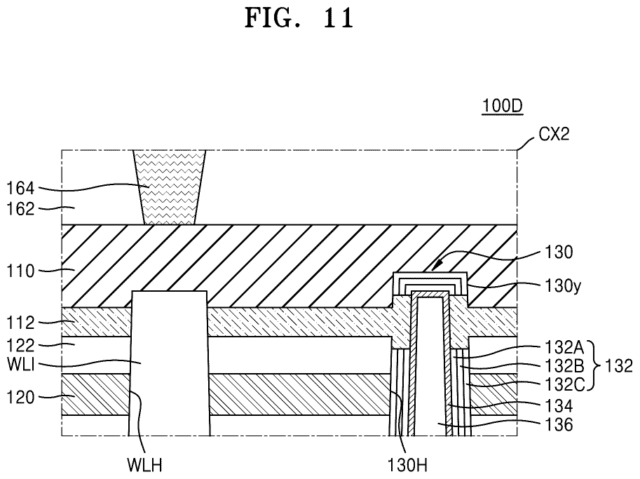

FIG. 11 is a cross-sectional view of a semiconductor device 100D according to embodiments of the present inventive concept.

Referring to FIG. 11, a lateral common source layer 112 may be further located between the common source layer 110 and the mold insulating layer 122. The lateral common source layer 112 may at least partially surround the sidewall of the channel layer 134 and may be electrically connected to the channel layer 134. For example, at a second end 130y of the channel 130, an upper surface of the channel layer 134 might not directly contact the common source layer 110 and may be covered by the gate insulating layer 132, and the gate insulating layer 132 might not be disposed on the portions of the sidewalls of the channel layer 134 that are at least partially surrounded by the lateral common source layer 112.

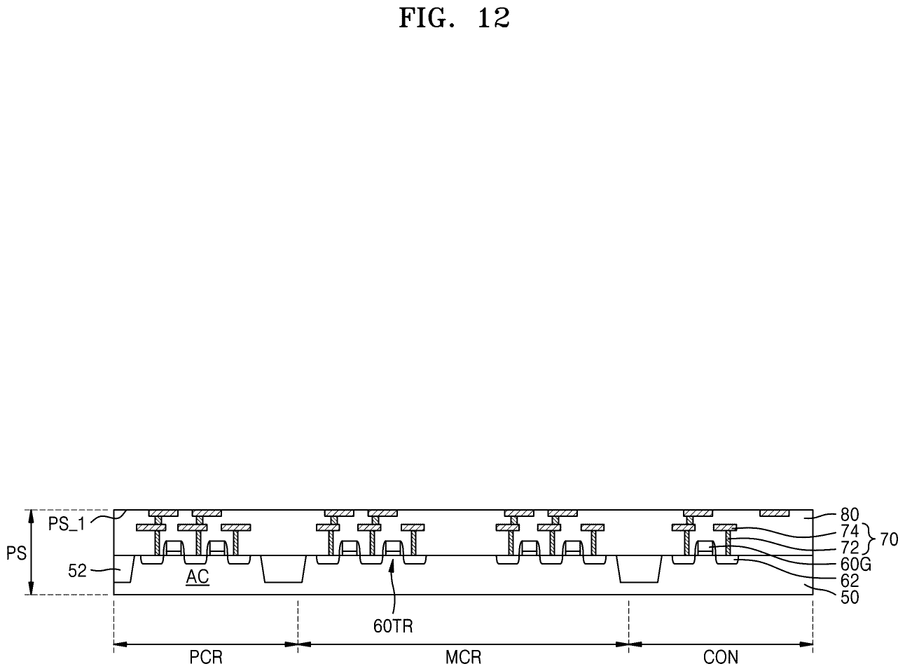

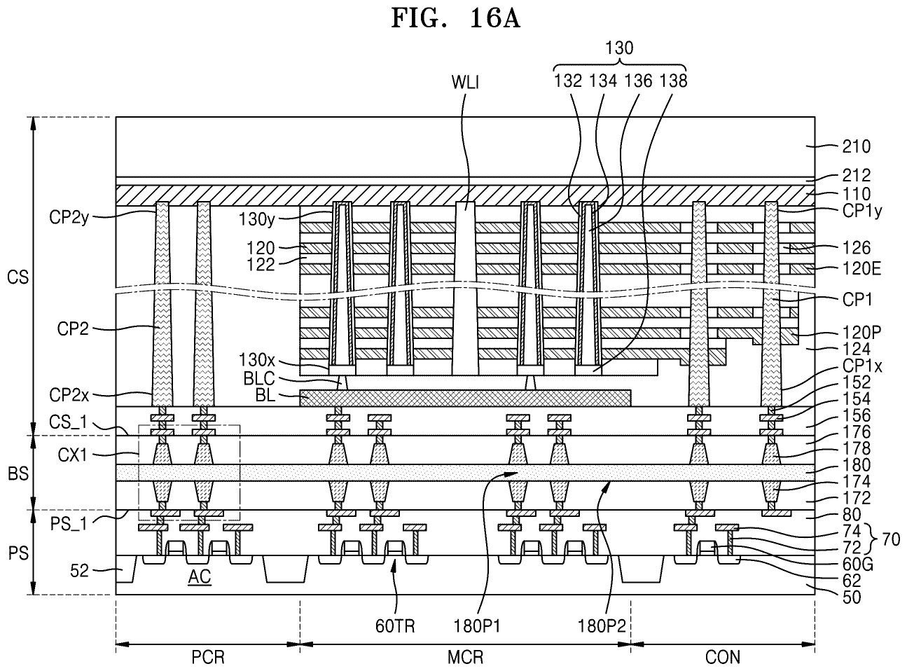

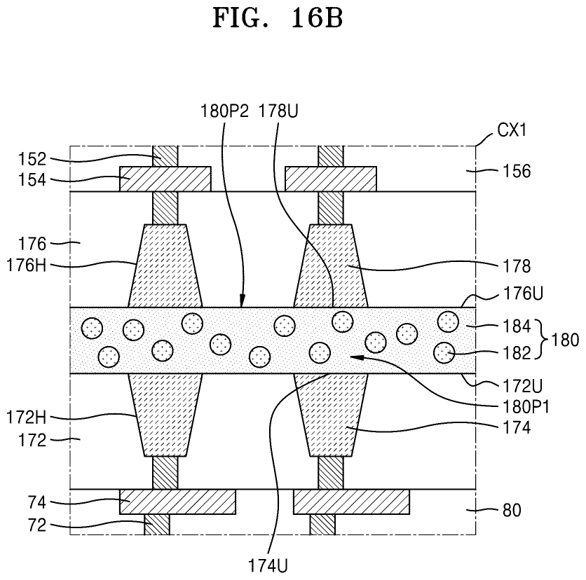

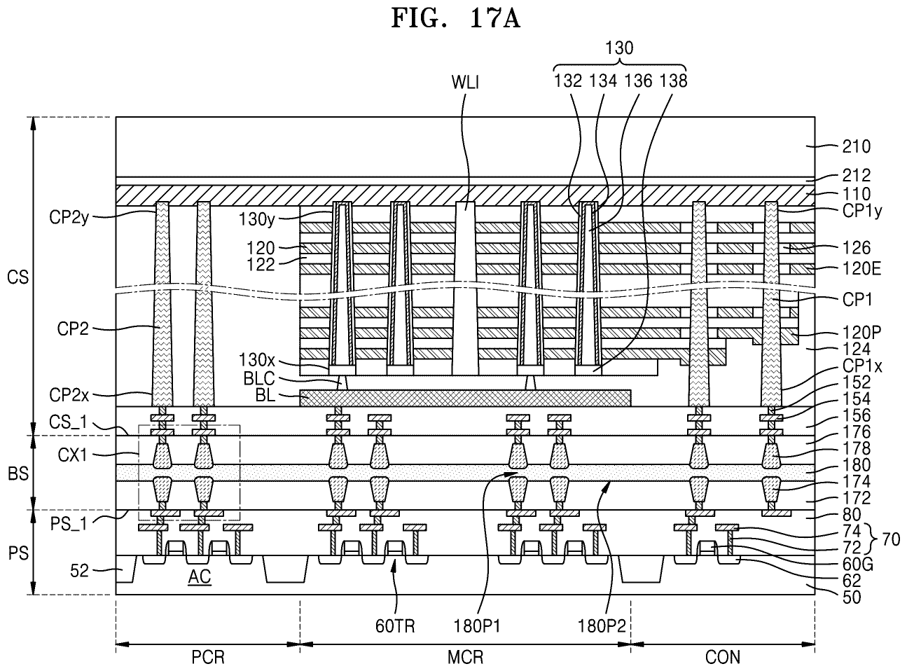

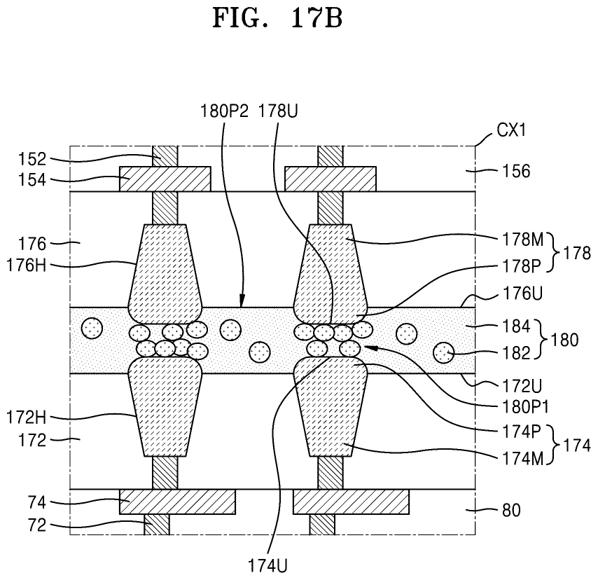

FIGS. 12 to 15, 16A, 16B, 17A, 17B, 18, and 19 are schematic diagrams illustrating a method of manufacturing the semiconductor device 100, according to embodiments of the present inventive concept. In detail, FIGS. 12 to 15, 16A, 17A, 18, and 19 are cross-sectional views taken along line A1-A1′ of FIG. 4, and FIGS. 16B and 17B are enlarged views of the portion CX1 of FIGS. 16A and 17A.

Referring to FIG. 12, the peripheral circuit structure PS may be formed. The peripheral circuit structure PS may include the peripheral circuit transistor 60TR and the peripheral circuit interconnection structure 70 that are disposed on a substrate 50. An active region AC may be defined on the substrate 50 by a device isolation layer 52, and a plurality of peripheral circuit transistors 60TR may be formed on the active region AC. The peripheral circuit transistors 60TR may each include the peripheral circuit gate 60G and the source/drain regions 62 that are located in portions of the substrate 50 on both sides of the peripheral circuit gate 60G.

The peripheral circuit contact 72 and the peripheral circuit interconnection layer 74 electrically connected to the peripheral circuit gate 60G and the source/drain region 62 may be formed on the substrate 50, and the interlayer insulating layer 80 covering the peripheral circuit contact 72 and the peripheral circuit interconnection layer 74 may be formed on the substrate 50. Here, the upper surface of the interlayer insulating layer 80 may be referred to as the first surface PS_1 of the peripheral circuit structure PS.

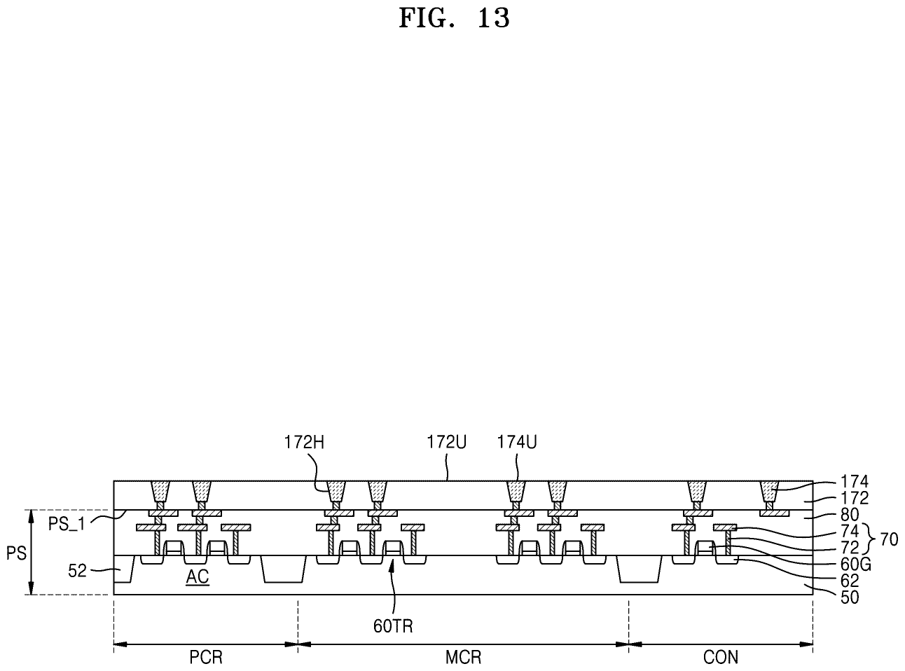

Referring to FIG. 13, the first insulating layer 172 may be formed on the first surface PS_1 of the peripheral circuit structure PS, and the first opening 172H may be formed by removing a portion of the first insulating layer 172. In embodiments of the present inventive concept, the first opening 172H may be formed to have an inclined side wall so that the upper width of the first opening 172H is greater than the lower width of the first opening 172H, and a step may be formed at the bottom of the first opening 172H. In embodiments of the present inventive concept, the first insulating layer 172 may include at least one of silicon carbon nitride, silicon nitride, silicon oxynitride, silicon oxide, and/or a low-k dielectric material.

Thereafter, the first bonding pad 174 may be formed within the first opening 172H. In embodiments of the present inventive concept, the first bonding pad 174 may be electrically connected to the peripheral circuit interconnection structure 70 of the peripheral circuit structure PS. The first bonding pad 174 may be formed through a plating process by using, for example, copper, nickel, aluminum, gold, tungsten, or alloys thereof. In embodiments of the present inventive concept, before forming the first bonding pad 174, a barrier metal film including titanium, tantalum, titanium nitride, tantalum nitride, or combinations thereof may be formed to have a small thickness on an inner wall of the first opening 172H.

In embodiments of the present inventive concept, a seed layer, such as copper, may be formed on the inner wall of the first opening 172H, and the first bonding pad 174 may be formed on the seed layer through a plating process. In embodiments of the present inventive concept, the upper side of the first bonding pad 174 may be planarized so that the upper surface of the first insulating layer 172 is exposed, and thus, the upper surface of the first bonding pad 174 may be disposed to be substantially coplanar with the upper surface of the first insulating layer 172.

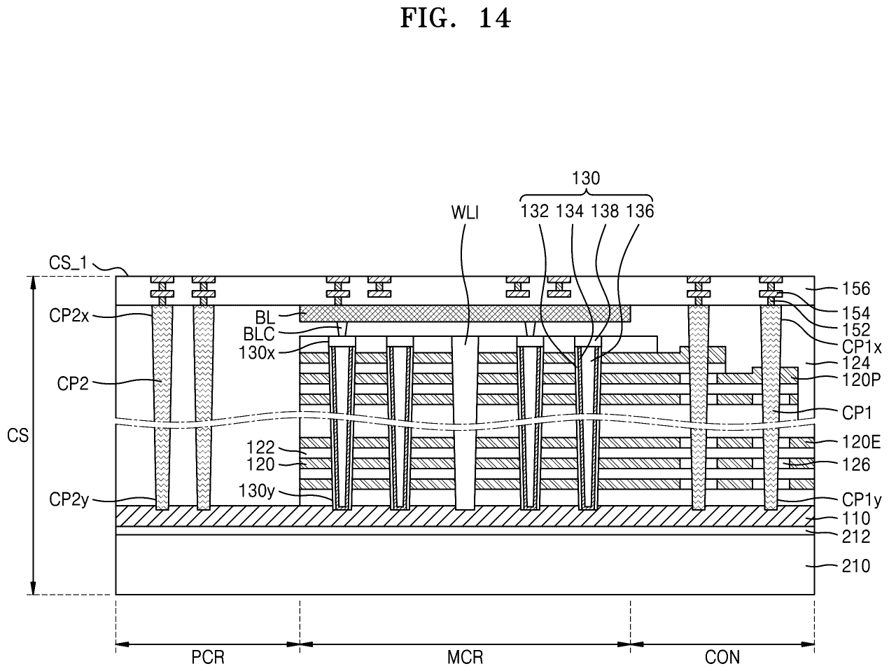

Referring to FIG. 14, the cell structure CS may be formed. To form the cell structure CS, an etch stop layer 212 may be formed on a sacrificial substrate 210, and the common source layer 110 may be formed on the etch stop layer 212. Thereafter, the gate electrodes 120 and the mold insulating layers 122 may be sequentially formed on the common source layer 110, and the channel 130 passing through the gate electrodes 120 and the mold insulating layers 122 in the cell region MCR may be formed. The extension 120E and the pad portion 120P may be formed by patterning the gate electrodes 120 and the mold insulating layers 122 in the connection region CON. Thereafter, the stack insulating layer 124 that covers the gate electrodes 120 and the pad portion 120P may be formed. The bit line contact BLC and the bit line BL that are electrically connected to the channel 130 may be formed in the cell region MCR.

Thereafter, the first plug CP1 passing through the stack insulating layer 124, the extension 120E, and the pad portion 120P in the connection region CON may be formed, and second plug CP2 passing through the stack insulating layer 124 in the peripheral circuit connection region PCR may be formed. Thereafter, the connection via 152 and the interconnection layer 154 that are electrically connected to the bit line BL, the first plug CP1, and the second plug CP2 may be formed, and the interlayer insulating film 156 covering the connection via 152 and the interconnection layer 154 may be formed. Here, the upper surface of the interlayer insulating film 156 may be referred to as the first surface CS_1 of the cell structure CS.

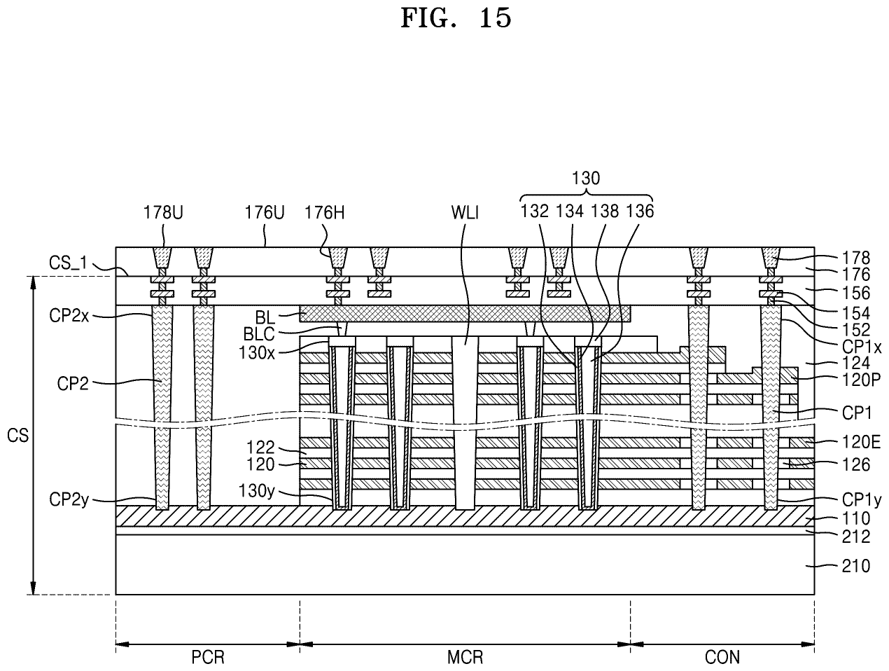

Referring to FIG. 15, the second insulating layer 176 may be formed on the first surface CS_1 of the cell structure CS, and the second opening 176H may be formed by removing a portion of the second insulating layer 176. In embodiments of the present inventive concept, the second opening 176H may be formed to have an inclined sidewall so that the upper width of the second opening 176H is greater than the lower width of the second opening 176H, and a step may be formed at the bottom of the second opening 176H. In embodiments of the present inventive concept, the second insulating layer 176 may include at least one of silicon carbon nitride, silicon nitride, silicon oxynitride, silicon oxide, and/or a low-k dielectric material.

Thereafter, the second bonding pad 178 may be formed within the second opening 176H. In embodiments of the present inventive concept, the second bonding pad 178 may be electrically connected to the bit line BL, the first plug CP1, and the second plug CP2 of the cell structure CS. The second bonding pad 178 may be formed through a plating process by using, for example, copper, nickel, aluminum, gold, tungsten, or alloys thereof. In embodiments of the present inventive concept, before forming the second bonding pad 178, a barrier metal film including titanium, tantalum, titanium nitride, tantalum nitride, or combinations thereof may be formed to have a thin thickness on an inner wall of the second opening 176H.

In embodiments of the present inventive concept, a seed layer, such as copper, may be formed on the inner wall of the second opening 176H, and the second bonding pad 178 may be formed on the seed layer through a plating process. In embodiments of the present inventive concept, the upper side of the second bonding pad 178 may be planarized so that the upper surface of the second insulating layer 176 is exposed, and thus, the upper surface of the second bonding pad 178 may be substantially coplanar with the upper surface of the second insulating layer 176.

Referring to FIGS. 16A and 16B, the cell structure CS may be located on the peripheral circuit structure PS with the anisotropic conductive adhesive layer 180 disposed between the cell structure CS and the peripheral circuit structure PS. For example, the first surface of the anisotropic conductive adhesive layer 180 may be in contact with the first insulating layer 172 and the first bonding pad 174 and the second surface of the anisotropic conductive adhesive layer 180 may be in contact with the second insulating layer 176 and the second bonding pad 178 so that the first surface CS_1 of the cell structure CS is disposed to be relatively close to the first surface PS_1 of the peripheral circuit structure PS. For example, the first surface CS_1 of the cell structure CS is disposed to face the first surface PS_1 of the peripheral circuit structure PS.

In embodiments of the present inventive concept, the anisotropic conductive adhesive layer 180 may include the conductive particles 182 that are dispersed within the adhesive member 184. In embodiments of the present inventive concept, the conductive particles 182 may include at least one of gold, silver, copper, nickel, aluminum, zinc, tin, lead, indium, and/or palladium. The adhesive member 184 may include at least one of epoxy resin, styrene resin, silicone resin, acrylic resin, polyolefin resin, melamine resin, urethane resin, phenol resin, polyester resin, nitrile rubber, and/or styrene-butadiene rubber.

The anisotropic conductive adhesive layer 180 may include the first portion 180P1 and the second portion 180P2. The first portion 180P1 may refer to a portion of the anisotropic conductive adhesive layer 180 that is located between the first bonding pad 174 and the second bonding pad 178, and the second portion 180P2 may refer to a portion of the anisotropic conductive adhesive layer 180 that is located between the first insulating layer 172 and the second insulating layer 176.

As shown in FIG. 16B, the first contact surface 172U of the first insulating layer 172 may be at substantially the same vertical level as that of the first connection surface 174U of the first bonding pad 174, and the second contact surface 176U of the second insulating layer 176 may be at substantially the same vertical level as that of the second connection surface 178U of the second bonding pad 178. Accordingly, the first portion 180P1 and the second portion 180P2 of the anisotropic conductive adhesive layer 180 may have substantially the same thickness as each other.

Referring to FIGS. 17A and 17B, a thermocompression process may be performed on the structure to which the cell structure CS and the peripheral circuit structure PS are attached. For example, the thermocompression process may be performed by exposing the structure, to which the cell structure CS and the peripheral circuit structure PS are attached, to a high temperature of, for example, about 100° C. or higher, about 150° C. or higher, or about 200° C. or higher and by simultaneously applying a compressive force to the structure to which the cell structure CS and the peripheral circuit structure PS are attached.

In embodiments of the present inventive concept, the volume of metal atoms, such as copper, in the first bonding pad 174 and the second bonding pad 178 may expand due to the thermocompression process. Accordingly, the first connection surface 174U of the first bonding pad 174 may protrude upwardly with respect to the first contact surface 172U of the first insulating layer 172, and the second connection surface 178U of the second bonding pad 178 may protrude downwardly with respect to the second contact surface 176U of the second insulating layer 176.

Here, a portion of the first bonding pad 174 that protrudes relative to the first contact surface 172U of the first insulating layer 172 is referred to as the first protruding region 174P, and a portion of the first bonding pad 174 located in the first opening 172H may be referred to as the first main region 174M. In addition, a portion of the second bonding pad 178 that protrudes relative to the second connection surface 178U is referred to as the second protruding region 178P, and a portion of the second bonding pad 178 located in the second opening 176H may be referred to as the second main region 178M.

As the volume of the first bonding pad 174 and the second bonding pad 178 expands, the conductive particles 182 may be in contact with and connect to at least one of the first bonding pad 174 and/or the second bonding pad 178 in the first portion 180P1 of the anisotropic conductive adhesive layer 180 that is located between the first bonding pad 174 and the second bonding pad 178 to provide an electrical connection path between the first bonding pad 174 and the second bonding pad 178.

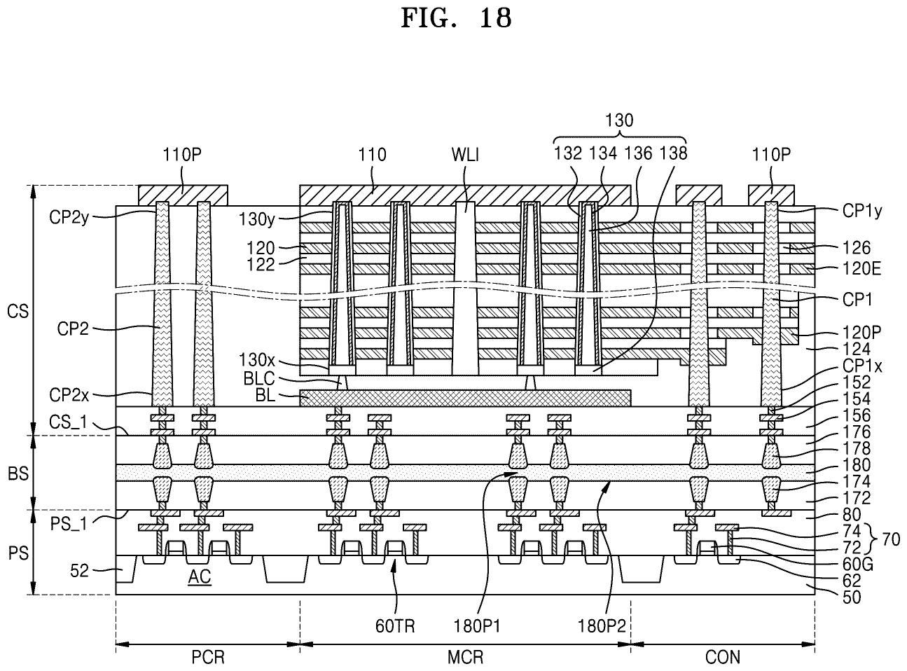

Referring to FIG. 18, the sacrificial substrate 210 and the etch stop layer 212 may be removed and the common source layer 110 may be exposed. Thereafter, a portion of the common source layer 110 may be removed, leaving the common source layer 110 in the cell region MCR and the extension 110P of the common source layer 110 in the connection region CON and the peripheral circuit connection region PCR.

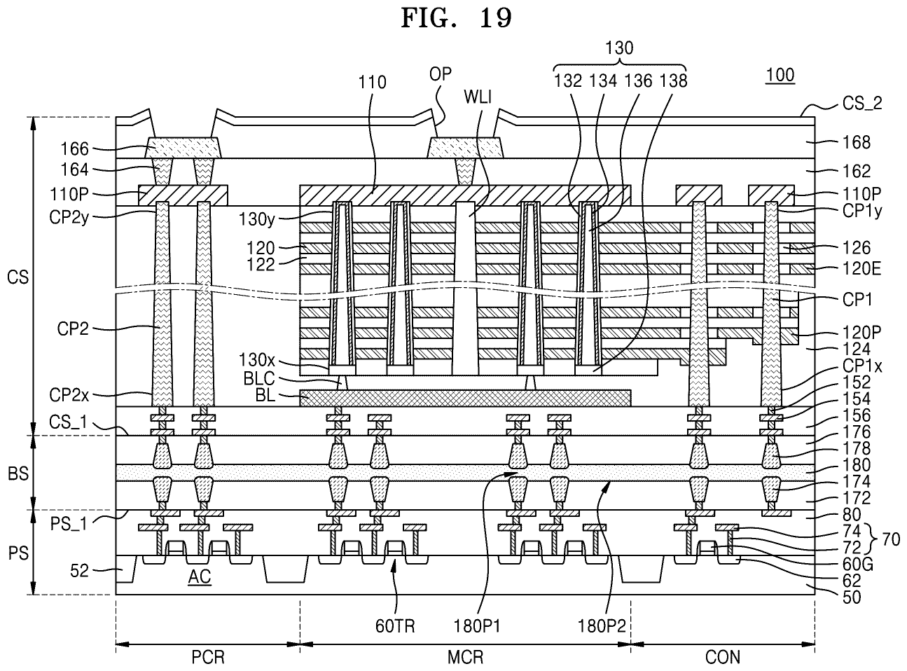

Referring to FIG. 19, the upper interlayer insulating film 162 may be formed on the common source layer 110, and rear vias 164 that are electrically connected to the common source layer 110 through the upper interlayer insulating film 162 may be formed. Thereafter, rear pads 166 may be formed on the upper interlayer insulating film 162.

The passivation layer 168 may be formed on the upper interlayer insulating film 162, and thereafter, a portion of the passivation layer 168 may be removed to form the opening OP that exposes the upper surface of the rear pads 166.

According to the embodiments described above, the cell structure CS may be attached to the peripheral circuit structure PS by using the anisotropic conductive adhesive layer 180. Because the first bonding pad 174 is not in direct contact with the second bonding pad 178 and an electrical path may be formed between the first bonding pad 174 and the second bonding pad 178 through the conductive particles 182, the difficulty of the bonding pad formation process may decrease and an electrical connection structure having increased reliability may be obtained.

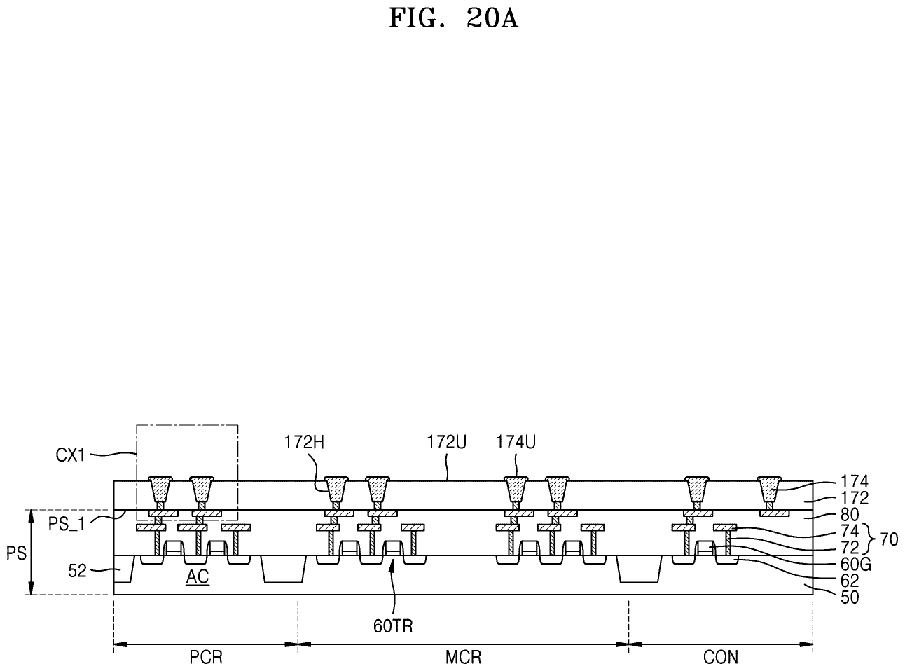

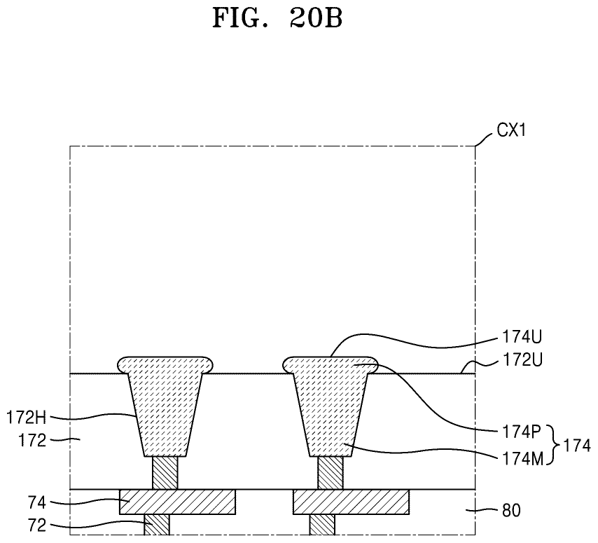

FIGS. 20A and 20B are cross-sectional views illustrating a method of manufacturing the semiconductor device 100C, according to embodiments between the first bonding pad 174 and the second bonding pad 178.

In the manufacturing method described above with reference to FIGS. 12 to 19, the volume of the first bonding pad 174 expands through a thermocompression process to form the first protruding region 174P, whereas in the manufacturing method described with reference to FIGS. 20A and 20B, the first protruding region 174P may be formed through a separate plating process.

First, the structure in which the first bonding pad 174 is formed within the first opening 172H of the first insulating layer 172 is formed by performing the process described above with reference to FIGS. 12 to 15.

Referring to FIGS. 20A and 20B, the first protruding region 174P may be formed by performing a plating process on the upper surface of the first bonding pad 174. In embodiments of the present inventive concept, the first protruding region 174P may be formed to have a horizontal width that is greater than the horizontal width of the first main region 174M located in the first opening 172H.

Referring again to FIG. 10, the second protruding region 178P may be formed by performing a plating process on the upper surface of the second bonding pad 178. In embodiments of the present inventive concept, the second protruding region 178P may be formed to have a horizontal width that is greater than the horizontal width of the second main region 178M located in the second opening 176H.

Thereafter, the semiconductor device 100C may be completed by performing the processes described above with reference to FIGS. 17A to 19.

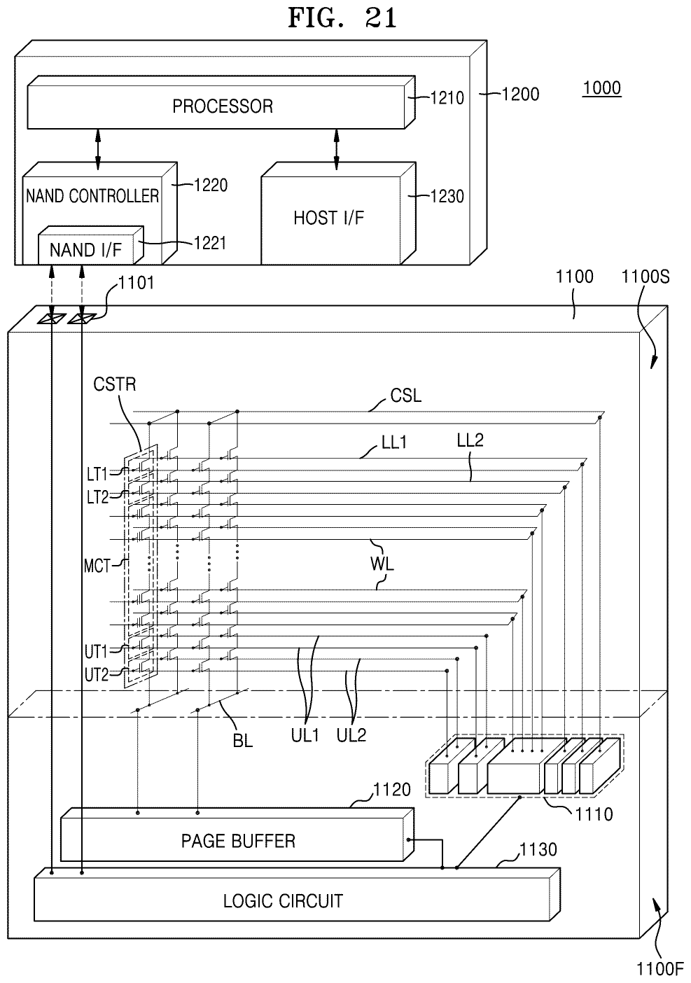

FIG. 21 is a diagram schematically illustrating a data storage system 1000 including a semiconductor device according to embodiments of the present inventive concept.

Referring to FIG. 21, the data storage system 1000 may include at least one semiconductor device 1100 and a memory controller 1200 that is electrically connected to the semiconductor device 1100. The data storage system 1000 may be, for example, a solid state drive (SSD) device including at least one semiconductor device 1100, a universal serial bus (USB), a computing system, a medical device, or a communication device.

The at least one semiconductor device 1100 may be a semiconductor device. For example, the semiconductor device 1100 may be a NAND flash semiconductor device including one of the semiconductor devices 10, 100, 100A, 100B, 100C, and 100D described above with reference to FIGS. 1 to 20. The at least one semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string select lines UL1 and UL2, first and second ground select lines LL1 and LL2, and a plurality of memory cell strings CSTR that are disposed between the bit line BL and the common source line CSL.

In the second structure 1100S, the memory cell strings CSTR may each include ground select transistors LT1 and LT2 adjacent to the common source line CSL, string select transistors UT1 and UT2 adjacent to the bit line BL, and a plurality of memory cell transistors MCT that are located between the ground select transistors LT1 and LT2 and the string select transistors UT1 and UT2. The number of ground select transistors LT1 and LT2 and the number of string select transistors UT1 and UT2 may be variously modified according to embodiments of the present inventive concept.

In embodiments of the present inventive concept, the ground select lines LL1 and LL2 may be connected to gate electrodes of the ground select transistors LT1 and LT2, respectively. The word line WL may be connected to a gate electrode of the memory cell transistor MCT. The string select lines UL1 and UL2 may be connected to gate electrodes of the string select transistors UT1 and UT2, respectively.

The common source line CSL, the ground select lines LL1 and LL2, the word lines WL, and the string select lines UL1 and UL2 may be connected to the row decoder 1110. The bit lines BL may be electrically connected to the page buffer 1120.

The semiconductor device 1100 may communicate with the memory controller 1200 through an I/O pad 1101 that is electrically connected to a logic circuit 1130. The I/O pad 1101 may be electrically connected to the logic circuit 1130.

The memory controller 1200 may include a processor 1210, a NAND controller 1220, and a host interface 1230. In embodiments of the present inventive concept, the data storage system 1000 may include a plurality of semiconductor devices 1100, and in this case, the memory controller 1200 may control the semiconductor devices 1100.

The processor 1210 may control overall operations of the data storage system 1000 including the memory controller 1200. The processor 1210 may operate according to certain firmware and may access the semiconductor device 1100 by controlling the NAND controller 1220. The NAND controller 1220 may include a NAND interface 1221 that processes communication with the semiconductor device 1100. Through the NAND interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host I/F 1230 may provide a communication function between the data storage system 1000 and an external host. When a control command is received from an external host through the host I/F 1230, the processor 1210 may control the semiconductor device 1100 in response to the control command.

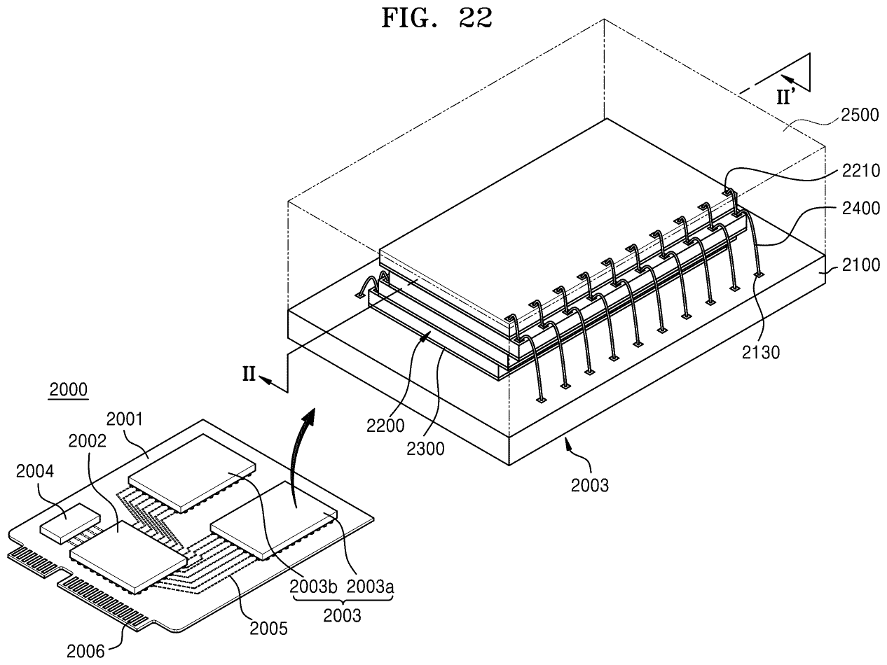

FIG. 22 is a perspective view schematically illustrating a data storage system 2000 including a semiconductor device according to embodiments of the present inventive concept.

Referring to FIG. 22, the data storage system 2000 according to an embodiment of the present inventive concept may include a main substrate 2001, a memory controller 2002 mounted on the main substrate 2001, one or more semiconductor packages 2003, and a DRAM 2004. The semiconductor package 2003 and the DRAM 2004 may be connected to the memory controller 2002 through a plurality of interconnection patterns 2005 that are formed on the main substrate 2001.

The main substrate 2001 may include a connector 2006 including a plurality of pins coupled to an external host. The number and arrangement of the pins of the connector 2006 may vary depending on a communication interface that is between the data storage system 2000 and the external host. In embodiments of the present inventive concept, the data storage system 2000 may communicate with an external host according to any one of interfaces such as a universal serial bus (USB), a peripheral component interconnect express (PCI-Express), a serial advanced technology attachment (SATA), M-Phy for a universal flash storage (UFS), etc. In embodiments of the present inventive concept, the data storage system 2000 may operate by power supplied from an external host through the connector 2006. The data storage system 2000 may further include a power management integrated circuit (PMIC) for distributing power supplied from the external host to the memory controller 2002 and the semiconductor package 2003.

The memory controller 2002 may write data to or read data from the semiconductor package 2003, and may increase an operating speed of the data storage system 2000.

The DRAM 2004 may be a buffer memory for mitigating a speed difference between the semiconductor package 2003 as a data storage space and the external host. The DRAM 2004 included in the data storage system 2000 may also operate as a kind of cache memory, and may provide a space for temporarily storing data in a control operation for the semiconductor package 2003. When the DRAM 2004 is included in the data storage system 2000, the memory controller 2002 may further include a DRAM controller for controlling the DRAM 2004 in addition to the NAND controller for controlling the semiconductor package 2003.

The semiconductor package 2003 may include first and second semiconductor packages 2003a and 2003b that are apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200, which are disposed on the package substrate 2100, an adhesive layer 2300 disposed on a lower surface of each of the semiconductor chips 2200, a connection structure 2400, which electrically connects the semiconductor chips 2200 to the package substrate 2100, and a molding layer 2500, which covers the semiconductor chips 2200 and the connection structure 2400 on the package substrate 2100.

The package substrate 2100 may be a PCB including a plurality of package upper pads 2130. Each of the semiconductor chips 2200 may include an I/O pad 2210. The I/O pad 2210 may correspond to the I/O pad 1101 of FIG. 29. Each of the semiconductor chips 2200 may include at least one of the semiconductor devices 10, 100, 100A, 100B, 100C, and 100D described above with reference to FIGS. 1 to 20.

In embodiments of the present inventive concept, the connection structure 2400 may be a bonding wire electrically connecting the I/O pad 2210 to the package upper pad 2130. Accordingly, in the first and second semiconductor packages 2003a and 2003b, the semiconductor chips 2200 may be electrically connected to each other by a bonding wire method, and may be electrically connected to the package upper pad 2130 of the package substrate 2100. In embodiments of the present inventive concept, in the first and second semiconductor packages 2003a and 2003b, the semiconductor chips 2200 may be electrically connected to each other by a connection structure including a through-silicon via (TSV), instead of the bonding wire type connection structures 2400.

In embodiments of the present inventive concept, the memory controller 2002 and the semiconductor chips 2200 may be included in a single package. In embodiments of the present inventive concept, the memory controller 2002 and the semiconductor chips 2200 may be mounted on a separate interposer substrate, which is different from the main substrate 2001, and the memory controller 2002 may be connected to the semiconductor chips 2200 by an interconnection that is formed on the interposer substrate.

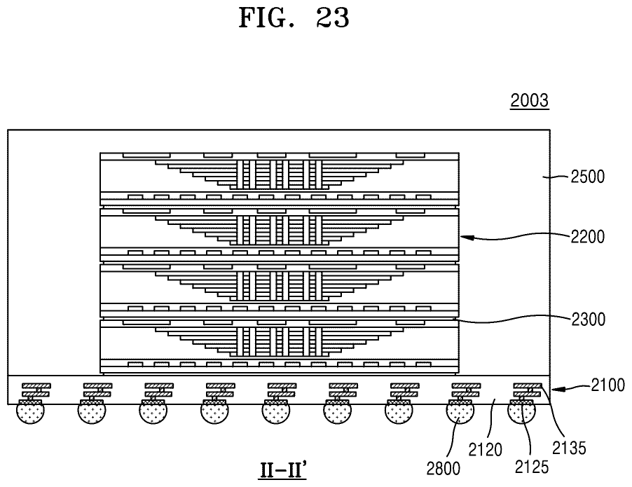

FIG. 23 is a schematic cross-sectional view of semiconductor packages 2003 according to embodiments of the present inventive concept. FIG. 23 is a cross-sectional view taken along line II-II′ of FIG. 22.

Referring to FIG. 23, in the semiconductor package 2003, the package substrate 2100 may be a printed circuit substrate. The package substrate 2100 may include a package substrate body portion 2120, a plurality of package upper pads 2130 (refer to FIG. 22), which are disposed on an upper surface of the package substrate body portion 2120, a plurality of lower pads 2125, which are disposed on a lower surface of the package substrate body portion 2120 or exposed through the lower surface of the package substrate body portion 2120, and a plurality of internal interconnections 2135 electrically connecting the package upper pads 2130 (refer to FIG. 22) to the lower pads 2125 in the package substrate body portion 2120. As shown in FIG. 23, the package upper pads 2130 may be electrically connected to the connection structures 2400. As shown in FIG. 23, the lower pads 2125 may be connected to the interconnection patterns 2005, which are disposed on the main substrate 2001 of the data storage system 2000 shown in FIG. 22 through a plurality of conductive bumps 2800. Each of the semiconductor chips 2200 may include at least one of the semiconductor devices 10, 100, 100A, 100B, 100C, and 100D described above with reference to FIGS. 1 to 20.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
a peripheral circuit structure including a substrate and a circuit that is disposed on the substrate;
a cell structure disposed on the peripheral circuit structure and including a plurality of gate electrodes and a channel that extends in a vertical direction through the gate electrodes; and
a bonding structure located between the peripheral circuit structure and the cell structure,
wherein the bonding structure includes:
a first insulating layer attached to the peripheral circuit structure;
a first bonding pad disposed on the peripheral circuit structure and electrically connected to the circuit of the peripheral circuit structure;
a second insulating layer attached to the cell structure;
a second bonding pad disposed on the cell structure and electrically connected to the plurality of gate electrodes; and
an anisotropic conductive adhesive layer located between the first insulating layer and the second insulating layer and between the first bonding pad and the second bonding pad, and including a plurality of conductive particles.

2. The semiconductor device of claim 1, wherein
the first insulating layer includes a first contact surface that is attached to the anisotropic conductive adhesive layer,
the first bonding pad includes a first connection surface that is attached to the anisotropic conductive adhesive layer,
the first connection surface of the first bonding pad protrudes in a direction toward the cell structure and beyond the first contact surface of the first insulating layer,
the second insulating layer includes a second contact surface that is attached to the anisotropic conductive adhesive layer,
the second bonding pad includes a second connection surface that is attached to the anisotropic conductive adhesive layer, and
the second connection surface of the second bonding pad protrudes in a direction toward the peripheral circuit structure and beyond the second contact surface of the second insulating layer.

3. The semiconductor device of claim 2, wherein
the anisotropic conductive adhesive layer includes a first portion that is located between the first bonding pad and the second bonding pad, and
the plurality of conductive particles included in the first portion of the anisotropic conductive adhesive layer are in contact with at least one of the first bonding pad or the second bonding pad between the first bonding pad and the second bonding pad.

4. The semiconductor device of claim 3, wherein
the first bonding pad is not in direct contact with the second bonding pad, and
the first bonding pad is electrically connected to the second bonding pad through the plurality of conductive particles that are included in the first portion of the anisotropic conductive adhesive layer.

5. The semiconductor device of claim 3, wherein a distance between the first contact surface of the first insulating layer and the second contact surface of the second insulating layer is greater than a distance between the first connection surface of the first bonding pad and the second connection surface of the second bonding pad.

6. The semiconductor device of claim 3, wherein
the first connection surface of the first bonding pad protrudes outwardly beyond the first contact surface of the first insulating layer,
a portion of the first connection surface has a rounded shape,
the second connection surface of the second bonding pad protrudes outwardly beyond the second contact surface of the second insulating layer, and
a portion of the second connection surface has a rounded shape.

7. The semiconductor device of claim 1, wherein
the first insulating layer includes a first opening,
the first bonding pad includes a first main region, which is disposed within the first opening of the first insulating layer, and a first protruding region, which is disposed on the main region and outside the first opening of the first insulating layer, and
a width of the first protruding region in a first horizontal direction is larger than a width of the first main region in the first horizontal direction.

8. The semiconductor device of claim 1, wherein
the first insulating layer includes at least one of silicon carbon nitride, silicon nitride, silicon oxynitride, silicon oxide, or a low-k dielectric material, and
the second insulating layer includes at least one of silicon carbon nitride, silicon nitride, silicon oxynitride, silicon oxide, or a low-k dielectric material.

9. The semiconductor device of claim 1, wherein
the first insulating layer is not in direct contact with the second insulating layer, and
the anisotropic conductive adhesive layer is located between the first insulating layer and the second insulating layer.

10. A semiconductor device comprising:
a peripheral circuit structure including a substrate and a circuit that is disposed on the substrate;
a cell structure disposed on the peripheral circuit structure and including a plurality of gate electrodes and a channel that extends in a vertical direction through the gate electrodes; and
a bonding structure located between the peripheral circuit structure and the cell structure,
wherein the bonding structure includes:
a first insulating layer attached to a first surface of the peripheral circuit structure and including a first opening;
a first bonding pad disposed within the first opening of the first insulating layer and electrically connected to the circuit of the peripheral circuit structure;
a second insulating layer attached to a first surface of the cell structure and including a second opening;
a second bonding pad disposed within the second opening of the second insulating layer and electrically connected to the plurality of gate electrodes; and
an anisotropic conductive adhesive layer located between the first insulating layer and the second insulating layer and between the first bonding pad and the second bonding pad, and including a plurality of conductive particles,
wherein a portion of the first bonding pad is disposed outside of the first opening of the first insulating layer and protrudes in a direction toward the cell structure, and
a portion of the second bonding pad is disposed outside of the second opening and protrudes in a direction toward the peripheral circuit structure.

11. The semiconductor device of claim 10, wherein
the first bonding pad includes:
a first main region disposed within the first opening of the first insulating layer; and
a first protruding region integrally connected to the first main region and contacting the anisotropic conductive adhesive layer, and
the second bonding pad includes:
a second main region disposed within the second opening of the second insulating layer; and
a second protruding region integrally connected to the second main region and contacting the anisotropic conductive adhesive layer.

12. The semiconductor device of claim 11, wherein
the anisotropic conductive adhesive layer includes a first portion and a second portion,
the first portion is located between the first protruding region of the first bonding pad and the second protruding region of the second bonding pad,
the second portion is located between the first insulating layer and the second insulating layer, and
a thickness of the first portion of the anisotropic conductive adhesive layer is less than a thickness of the second portion of the anisotropic conductive adhesive layer.

13. The semiconductor device of claim 12, wherein
the plurality of conductive particles included in the first portion of the anisotropic conductive adhesive layer electrically connect the first protruding region of the first bonding pad to the second protruding region of the second bonding pad, and
the plurality of conductive particles included in the second portion of the anisotropic conductive adhesive layer do not electrically connect the first insulating layer to the second insulating layer.

14. The semiconductor device of claim 11, wherein the first main region of the first bonding pad includes a void that is disposed in the first main region, and the first protruding region of the first bonding pad does not include a void in the first protruding region.

15. The semiconductor device of claim 11, wherein
the first insulating layer includes a first contact surface that is attached to the anisotropic conductive adhesive layer,
the first protruding region of the first bonding pad protrudes in a direction toward the cell structure and beyond the first contact surface of the first insulating layer,
the second insulating layer includes a second contact surface that is attached to the anisotropic conductive adhesive layer, and
the second protruding region of the second bonding pad protrudes in a direction toward the peripheral circuit structure and beyond the second contact surface of the second insulating layer.

16. The semiconductor device of claim 15, wherein a distance between the first contact surface of the first insulating layer and the second contact surface of the second insulating layer is larger than a distance between the first protruding region of the first bonding pad and the second protruding region of the second bonding pad.

17. The semiconductor device of claim 15, wherein
the first protruding region of the first bonding pad has a rounded shape, and
the second protruding region of the second bonding pad has a rounded shape.

18. The semiconductor device of claim 15, wherein
the first protruding region of the first bonding pad has a flat surface, and
the second protruding region of the second bonding pad has a flat surface.

19. The semiconductor device of claim 15, wherein
the first protruding region of the first bonding pad has a width that is larger than a width of the first main region, and
the second protruding region of the second bonding pad has a width that is larger than a width of the second main region.

20. A semiconductor device comprising:
a peripheral circuit structure including a substrate and a circuit that is disposed on the substrate;
a cell structure disposed on the peripheral circuit structure, wherein the cell structure includes a plurality of gate electrodes and a channel extending in a vertical direction through the plurality of gate electrodes, wherein the cell structure further includes a plurality of memory strings to which the channel is connected in the vertical direction; and
a bonding structure located between the peripheral circuit structure and the cell structure,
wherein the bonding structure includes:
a first insulating layer attached to a first surface of the peripheral circuit structure and including a first opening;
a first bonding pad disposed within the first opening of the first insulating layer and electrically connected to the circuit;
a second insulating layer attached to a first surface of the cell structure and including a second opening;
a second bonding pad disposed within the second opening of the second insulating layer and electrically connected to the plurality of gate electrodes; and
an anisotropic conductive adhesive layer located between the first insulating layer and the second insulating layer and between the first bonding pad and the second bonding pad, and including a plurality of conductive particles,
wherein the first insulating layer includes a first contact surface that is attached to the anisotropic conductive adhesive layer,
the first bonding pad includes a first connection surface that is attached to the anisotropic conductive adhesive layer,
the first connection surface of the first bonding pad protrudes in a direction toward the cell structure and beyond the first contact surface of the first insulating layer,
the second insulating layer includes a second contact surface that is attached to the anisotropic conductive adhesive layer,
the second bonding pad includes a second connection surface that is attached to the anisotropic conductive adhesive layer, and
the second connection surface of the second bonding pad protrudes in a direction toward the peripheral circuit structure and beyond the second contact surface of the second insulating layer.
